(19) United States
(12) Patent Application Publication
(10) Pub. No.: US 2022/0155159 A1
(43) Pub. Date: May 19, 2022

(54) MICROSCALE AND NANOSCALE STRUCTURED ELECTROMECHANICAL TRANSDUCERS EMPLOYING COMPLIANT DIELECTRIC SPACERS

(71) Applicant: Massachusetts Institute of Technology, Cambridge, MA (US)

(72) Inventors: Vladimir BULOVIC, Lexington, MA (US); Apoorva MURARKA, Cambridge, MA (US); Damien REARDON, Maastricht (NL); Jeffrey H. LANG, Sudbury, MA (US); Jinchi HAN, Cambridge, MA (US)

(21) Appl. No.: 17/439,556

(22) PCT Filed: Mar. 13, 2020
(86) PCT No.: PCT/US2020/022661

§ 371 Date: Sep. 15, 2021

Related U.S. Application Data
(60) Provisional application No. 62/818,917, filed on Mar. 15, 2019.

(51) Int. Cl. G01L 1/14; G06F 3/01; B06B 1/02

(52) U.S. Cl. CPC G01L 1/148; G01L 1/146; B81B 2201/0264; B06B 1/0292; G06F 3/016

(57) ABSTRACT

Described embodiments provide an electromechanical transducer including a mechanically compliant, elastically deformable array of dielectric shells. A first electrically conductive electrode is disposed on a first surface of the array. A second electrically conductive electrode is disposed on a second surface of the array, where the second surface opposes the first surface. The array is configured to be mechanically compliant and elastically deformable in response to one or more incident forces applied to the electromechanical transducer.

### CROSS-REFERENCE TO RELATED APPLICATIONS

This application claims the benefit of the filing date of U.S. provisional application No. 62/818,917, filed on Mar. 15, 2019, the teachings of which are incorporated herein by reference in their entireties.

### BACKGROUND

Microelectromechanical and nanoelectromechanical systems (MEMS/NEMS) are devices commonly employed in electromechanical sensors and actuators that typically include both mechanical and electronic components in a size ranging from hundreds of micrometers (e.g., for MEMS) to tens of nanometers (e.g., for NEMS). Approximately 15 billion MEMS sensors were deployed in various devices in 2015 and it has been predicted that a trillion sensors and actuators will be deployed by 2025, fueled by a need to sense and collect data from myriad phenomena in and across networked devices that form the Internet of Things (IoT). The ability to include MEMS sensors and actuators in increasing numbers of devices has largely been driven by technological advances in micromachining and processing and the increasing demand for electronics devices that employ MEMS sensors and actuators, such as smartphones, tablets, wearables, portable computing systems, videogaming systems, and so on.

Beyond technological advances and demand, another driver for the rapid rate of adoption of MEMS devices in the past decade has been the reduction in their fabrication cost due to economies of scale enabled by integrated circuit (IC) foundries repurposing their 8-inch-diameter wafer equipment for making MEMS/NEMS devices. However, this means that MEMS/NEMS devices are developed and manufactured using IC fab material platforms, equipment, and design parameters and, thus, can be limited in size, function, and cost. Thus, as MEMS/NEMS devices continue to be deployed in greater numbers in wider applications, it is desirable to develop improved MEMS/NEMS material platforms and device architectures to decrease the technological threshold that must be crossed to achieve new functions in micro- and nano-structured sensors and actuators.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

One aspect provides an electromechanical transducer including a mechanically compliant, elastically deformable array of dielectric shells. A first electrically conductive electrode is disposed on a first surface of the array. A second electrically conductive electrode is disposed on a second surface of the array, where the second surface opposes the first surface. The array is configured to be mechanically compliant and elastically deformable in response to one or more incident forces applied to the electromechanical transducer.

Some described embodiments provide an electromechanical transducer including a processing circuit electrically coupled to the first and second electrically conductive electrodes. The processing circuit measures a variable capacitance between the first and second electrically conductive electrodes. The variable capacitance is caused by mechanical compliance and elastic deformation of the array due to a varying of the incident forces applied to the electromechanical transducer.

In some embodiments, the processing circuit varies an electrostatic force between the first and second electrically conductive electrodes to cause a varying mechanical compliance and elastic deformation of the array, thereby resulting in emission of a correspondingly varying pressure wave from the electromechanical transducer.

In some embodiments, the processing circuit may include one or more of: a direct current (DC) voltage source, an alternating current (AC) voltage source, a DC current source, an AC current source, an application-specific integrated circuit (ASIC), a microprocessor, a digital signal processor (DSP), a digital-to-analog (DAC) converter, an analog-to-digital converter (ADC), an amplifier, a boost converter, and a power source.

In some embodiments, one or both of the electrically conductive electrodes is planarized.

In some embodiments, one of the first and second electrically conductive electrodes include a substrate to which the transducer is bonded.

In some embodiments, one of the first and second electrically conductive electrodes include a conductive layer bonded to an insulating or semiconducting substrate.

In some embodiments, the transducer includes a substrate that is coated with an electrically conducting film or has an integrated conducting region such that the substrate is operable as one of the first and second electrically conductive electrodes.

In some embodiments, one or more physical properties of the shells are related to a corresponding responsiveness of the electromechanical transducer.

In some embodiments, the one or more physical properties of the shells may include one or more of: a shell diameter, a shell characteristic length, a shell shape, a shell material, and a shell wall thickness. The responsiveness of the electromechanical transducer may include one or more of: a stiffness of the array, a deflection stroke length of at least one of the first and second conductive electrodes, spectral sensitivity of the electromechanical transducer, and a signal-to-noise ratio of the electromechanical transducer.

In some embodiments, the shell diameter is between approximately 2 nm and approximately 500 μm.

In some embodiments, one or more of the shells in the array enclose a fluid within a volume of the shell.

In some embodiments, the shells may be implemented using at least one of: silica, soda-lime glass, borosilicate glass, fiberglass, or poly(methyl methacrylate). Each of the first and second electrically conductive electrodes may be implemented using at least one of: a conductive metal, a conductive metal oxide, graphene, parylene, a conductive polymer, or doped silicon. The substrate of the electromechanical transducer may be implemented using at least one of: glass, quartz, silicon, a plastic, IZO, AZO, ITO, a conductive metal oxide coated polymer, a conductive metal oxide coated glass, or a flexible polymer.

In some embodiments, the one or more applied forces are static or time-varying forces including at least one of: an electrostatic force, a solid contact pressure, a haptic pressure, a fluid pressure wave, a sound wave, and an ultrasound wave.

In some embodiments, the electromechanical transducer is optically transparent in a spectral band including one or more of: infra-red (IR), visible light, or ultraviolet (UV).

In some embodiments, the array comprises a plurality of layers of dielectric shells.

In another aspect, a method of using an electromechanical transducer is provided. The transducer includes a mechanically compliant, elastically deformable array of dielectric shells, a first electrically conductive electrode disposed on a first surface of the array, and a second electrically conductive electrode disposed on a second surface of the array. The second surface opposes the first surface. The first and second electrically conductive electrodes are electrically coupled to a processing circuit. The method includes measuring, by the processing circuit, a variable capacitance between the first and second electrically conductive electrodes. The variable capacitance is caused by mechanical compliance and elastic deformation of the array due to a varying incident pressure.

In some embodiments, the varying incident pressure includes at least one of: a solid contact pressure, a haptic pressure, a fluid pressure wave, a sound wave, and an ultrasound wave.

Another aspect provides a method of operating a transducer that includes a mechanically compliant, elastically deformable array of dielectric shells, a first electrically conductive electrode disposed on a first surface of the array, and a second electrically conductive electrode disposed on a second surface of the array. The second surface opposes the first surface, and the first and second electrically conductive electrodes are electrically coupled to a processing circuit. The method includes varying, by processing circuitry via an electrical signal, an electrostatic force between the first and second electrically conductive electrodes to cause a varying elastic deformation of the array varying a distance between the first and second electrically conductive electrodes. This results in emission of a correspondingly varying pressure wave from the electromechanical transducer.

In some embodiments, the electrical signal varies at audio or ultrasonic frequencies, and the emitted pressure wave varies at corresponding audio or ultrasonic frequencies.

In some embodiments, the emitted pressure wave is a haptic signal.

Another aspect provides a device that includes a substrate and a plurality of electromechanical transducers. Each transducer includes a mechanically compliant, elastically deformable array of dielectric shells, a first electrically conductive electrode disposed on a first surface of the array, and a second electrically conductive electrode disposed on a second surface of the array. The second surface is opposing the first surface and one of the first and second electrically conductive electrodes is bonded to the substrate. The device also includes processing circuitry coupled to each electromechanical transducer. The processing circuitry includes at least one of a variable capacitance measurement circuit and an actuator circuit. The processing circuitry is configured to operate the device as a phased array of sensors, a phased array of actuators, or a phased array of both sensors and actuators.

In some embodiments, each of the plurality of electromechanical transducers is bonded to a common substrate, and the common substrate is either a rigid substrate or a flexible substrate.

In some embodiments, each of the plurality of electromechanical transducers can be electronically addressed individually or in regions. In some embodiments, the device is optically transparent for integration with optical displays.

In some embodiments, the device is operated as an acoustic filter bank including an array of microphones. Each microphone may include an array of shells having a different effective mechanical stiffness, thereby tuning an acoustic sensitivity of each microphone to a desired band of frequencies. A received signal of each microphone contributes to a total sensed signal.

### BRIEF DESCRIPTION OF THE DRAWING FIGURES

Aspects, features, and advantages of the concepts, systems, and techniques described herein will become more fully apparent from the following detailed description, the appended claims, and the accompanying drawings in which like reference numerals identify similar or identical elements. Reference numerals that are introduced in the specification in association with a drawing figure may be repeated in one or more subsequent figures without additional description in the specification in order to provide context for other features. Furthermore, the drawings are not necessarily to scale, emphasis instead being placed on the concepts disclosed herein.

FIG. 1A shows a block diagram of a cross-sectional view of a variable-capacitance electromechanical structure including a lateral array of silica shells disposed between two conductive electrodes, in accordance with described embodiments;

FIG. 1B shows a cross-sectional view of a variable-capacitance electromechanical structure including a lateral array of silica shells disposed between two conductive electrodes, in accordance with described embodiments;

FIG. 2 shows a cross-sectional view of a variable-capacitance electromechanical structure where an electrode is distinct from an underlying substrate, in accordance with described embodiments;

FIG. 3 shows a cross-sectional view of a variable-capacitance electromechanical structure where an electrode is planarized for optical applications requiring surface sheen, in accordance with described embodiments;

FIG. 4 shows a cross-sectional view of a variable-capacitance electromechanical actuator, in accordance with described embodiments;

FIG. 5A shows a cross-sectional view of a variable-capacitance electromechanical actuator in a first, non-excited state, in accordance with described embodiments;

FIG. 5B shows a cross-sectional view of a variable-capacitance electromechanical actuator in a second, excited state, in accordance with described embodiments;

FIG. 6 shows a cross-sectional view of a variable-capacitance electromechanical structure having multiple layered arrays of silica shells disposed between two conductive electrodes, in accordance with described embodiments;

FIG. 7 shows a cross-sectional view of a variable-capacitance electromechanical structure having multiple layered arrays of silica shells of varying shell wall thickness, shell volume and shell shape, in accordance with described embodiments;

FIG. 8 shows a cross-sectional view of a variable-capacitance electromechanical structure having multiple regions of silica shells of varying shell wall thickness, shell volume and shell shape, in accordance with described embodiments;

FIG. 9 shows a cross-sectional view of a variable-capacitance electromechanical structure having multiple layered arrays of silica shells between two opposing electrical conductors operated under an actuation force, in accordance with described embodiments;

FIG. 10 shows the variable-capacitance electromechanical structure of FIG. 9 implemented in a microphone, pressure sensor, or ultrasound receiver, in accordance with described embodiments;

FIG. 11 shows the variable-capacitance electromechanical structure of FIG. 8 implemented in an acoustic filter bank consisting of an array of microphones on a single substrate, in accordance with described embodiments;

FIG. 12 shows the variable-capacitance electromechanical structure of FIG. 9 implemented in a speaker or ultrasound transmitter, in accordance with described embodiments;

FIG. 13 shows the variable-capacitance electromechanical structure of FIG. 9 implemented in a speaker or ultrasound transmitter having two or more bottom electrodes, in accordance with described embodiments;

FIG. 14 shows the variable-capacitance electromechanical structure of FIG. 9 implemented in a haptic device, in accordance with described embodiments;

FIG. 15 is a block diagram showing an array of variable-capacitance electromechanical devices disposed on a substrate, in accordance with described embodiments;

FIG. 16 is a block diagram showing an array of variable-capacitance electromechanical devices disposed on a flexible substrate with patterned electrodes, compliant silica shell spacer layers, and appropriate electronics for powering and addressing each electromechanical device, in accordance with described embodiments;

FIG. 17 is a flow diagram showing an illustrative process for operating electromechanical devices described herein as a transducer as an actuator or sensor, in accordance with described embodiments;

FIG. 18 shows a cross-sectional view of a sensor or actuator including a plurality of variable-capacitance electromechanical structures, in accordance with described embodiments;

FIG. 19 is a plot showing a magnitude and a phase of a transfer function over frequency of an illustrative embodiment of an electromechanical structure;

FIG. 20 is a plot showing a relationship between shell array thickness, porosity of the shell array, and resonance frequency of an illustrative embodiment of an electromechanical structure;

FIG. 21 shows a first series of plots showing a relationship between applied voltage amplitude, porosity of the shell array for silica shells, and displacement amplitude of the electromechanical structure, and a second series of plots showing a relationship between applied voltage amplitude, porosity of the shell array, and sound pressure level (SPL) at an actuation frequency of 1 kHz for shell array thicknesses of 1 μm, 10 μm, and 100 μm, in accordance with illustrative embodiments; and

FIG. 22 shows a first series of plots showing a relationship between applied voltage amplitude, porosity of the shell array for silica shells, and displacement amplitude of the electromechanical structure, and a second series of plots showing a relationship between applied voltage amplitude, porosity of the shell array, and sound pressure level (SPL) at an actuation frequency of 100 kHz for shell array thicknesses of 1 μm, 10 μm, and 100 μm, in accordance with illustrative embodiments.

### DETAILED DESCRIPTION

Described embodiments provide microelectromechanical and nanoelectromechanical systems (MEMS/NEMS) for sensors and actuators that can be fabricated and operated in a scalable manner over areas ranging from microns-squared to meters-squared, and on a variety of rigid, flexible, and/or transparent substrates such as plastics, semiconductors, glass, acrylics, metals, and polymer sheets. As will be described herein, embodiments provide arrays of micro- and/or nano-structured shells disposed between two or more opposing conductive electrodes to implement an area-scalable, mechanically compliant layer that can be actively displaced with the application of force/pressure. The mechanically compliant shell arrays form a dielectric layer between the two conducting plates (e.g., of a capacitor), such that the capacitance value of the transducer changes based upon the displacement of the mechanically compliant dielectric layer. The mechanically compliant shell arrays can be manipulated by an applied stimulus to provide an electromechanical actuator, or can be manipulated by external forces to provide an electromechanical sensor.

While described herein as generally being implemented as silica shells, it will be understood that in some embodiments, silica can be substituted with other, similar glass-like materials such as soda-lime glass, borosilicate glass, fiberglass, or poly(methyl methacrylate) (also known as PMMA or acrylic or plexiglass). The described silica shell system may be implemented via additive fabrication techniques that obviate the deleterious complexities and failure modes inherent in conventional micro-machining processes used for fabricating prevalent MEMS/NEMS sensors and actuators, such as sacrificial etching, subtractive patterning, and solvent-assisted release of compliant elements from growth substrates, among others.

MEMS device architectures commonly employ suspended membranes and plates, or piezoceramic materials to form a mechanically compliant sensing or actuation element. Suspended thin films such as membranes and plates are a commonly used approach in micro-structured electromechanical devices for implementing sensing and actuation functions. Membranes, plates, and cantilevers with thicknesses on the order of micrometers (microns) to hundreds of microns have been utilized in a variety of applications in microelectronic devices, including MEMS. However, when used as mechanically active elements, these membranes, plates, and cantilevers have been selected from a small and limited set of materials that includes silicon, polysilicon, silicon nitrides and other materials common in the integrated circuit fabrication industry. These materials have similar Young's modulus, Poisson's ratio, and thermal expansion coefficients.

Mechanically active thin film devices have been deployed in a limited number of applications such as MEMS microphones in smartphones, tablets, wireless headsets, smart home peripherals, and the like. Fabrication of such thin-film devices requires extensive micro-machining which often involves between 10 and 20 (or more) photolithography mask steps and frequently includes steps such as wafer-bonding. Such extensive fabrication flows, in turn, correlate to higher manufacturing complexity and cost, and lower yields. Further, such micro-machining processes also employ harsh chemical solvent treatments at elevated temperatures that readily degrade flexible polymeric substrates. As a result, the micro-structured substrate architecture is limited to standard wafer sizes since most current MEMS foundries offer processing on 4-, 6-, and 8-inch wafers only. Moreover, in the process of miniaturization for applications where mechanical displacement and strain has been a desired device function (ultrasound transducers, acoustic tweeters, microphones), MEMS elements have often been substituted with other bulk materials such as electrets, magnetic systems, and bulk piezoceramics that are often fabricated and prepackaged before being integrated as discrete components on IC boards. As a result, manufacturing and assembly complexity is increased. Beyond IC-based materials, there has been a growing effort in the past decade to utilize suspended 2-dimensional materials such as graphene sheets as mechanically compliant elements of sensors and actuators. However, a lack of commercially viable large-area manufacturing options has hindered the adoption of graphene as mechanically active membranes in sensors and actuators.

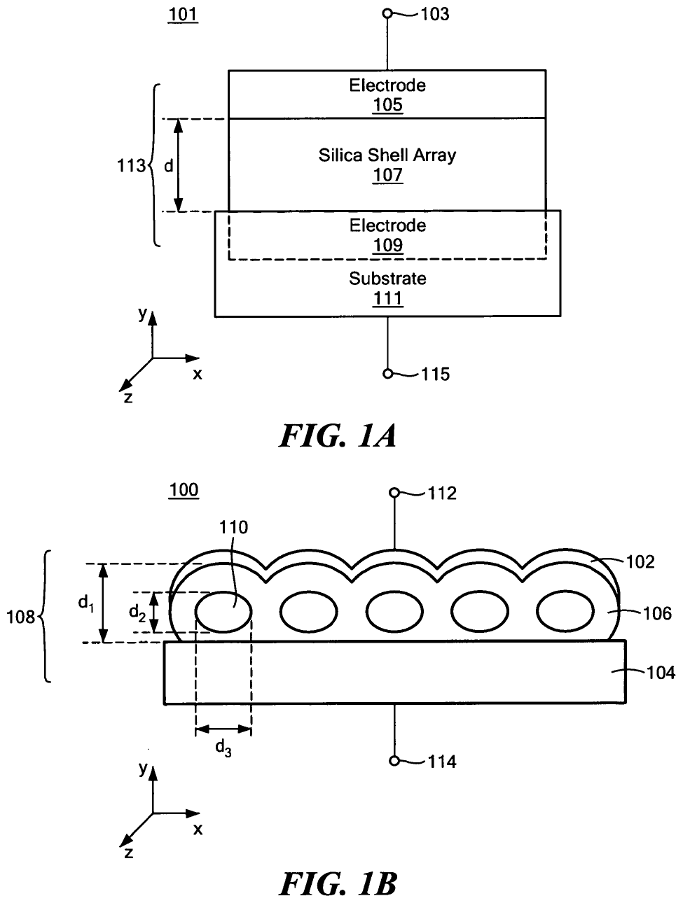

FIG. 1A shows a block diagram of a simplified cross-sectional view of an illustrative variable-capacitance electromechanical structure 101. As shown in FIG. 1A, variable-capacitance electromechanical structure 101 may include an array of micro/nano shell array 107 disposed between two conductive electrodes 105 and 109. As described generally herein, micro/nano shell array 107 may include one or more silica shells, but in some embodiments, silica can be substituted with other, similar glass-like materials such as soda-lime glass, borosilicate glass, fiberglass, PMMA, or other similar materials. The silica shell array 107 acts as a dielectric spacer layer in a variable capacitor 113 formed by electrodes 105 and 109. As indicated in FIG. 1A by the dashed lines, in some embodiments, electrode 109 may be integral with substrate 111 such that substrate 111 itself is electrically conducting and acts as one of the electrodes of variable capacitor 108. In other embodiments, electrode 109 may be a physically separate component disposed upon substrate 111.

Since the silica shells are mechanically compliant, the dielectric spacer layer can be stressed to increase or decrease a distance, d, between the electrically conducting surfaces of electrodes 105 and 109, by applying a force such as electrostatic, acoustic (e.g., audio or ultrasonic), pneumatic (e.g., static or dynamic), or haptic forces or pressures to structure 101. The applied force(s) deform silica shell array 107 in at least one dimension (shown as d in FIG. 1A). In described embodiments, electrical contact, shown as contacts 103 and 115, is made to each of electrodes 105 and 109. By varying the distance, d, between electrodes 105 and 109, the capacitance of variable capacitor 113 is varied, allowing electromechanical structure 101 to be used as a sensor or an actuator.

FIG. 1B shows a cross-sectional view of an illustrative variable-capacitance electromechanical structure 100. As shown in FIG. 1B, variable-capacitance electromechanical structure 100 may include a two-dimensional lateral array of silica micro/nano shells 106 disposed between two conductive electrodes 102 and 104. The silica shell array 106 acts as a dielectric spacer layer in a variable capacitor 108 formed by electrodes 102 and 104. Since the silica shells are mechanically compliant, the dielectric spacer layer can be stressed to increase or decrease a distance, d₁, between the electrically conducting surfaces of electrodes 102 and 104, thus forming a variable capacitance transducer 108 by applying a force to structure 100 that deforms silica shells 110 in at least one dimension (shown as d₂ in FIG. 1B).

As shown in FIG. 1B, an illustrative embodiment of the electromechanical device structure 100 may be implemented as a two-dimensional array 106 having a plurality of silica shells 110 disposed between two opposing electrically conductive surfaces, such as electrodes 102 and 104. Silica shells 110 are mechanically compliant and can be stressed and strained with the application of electrostatic, acoustic (e.g., audio or ultrasonic), pneumatic (e.g., static or dynamic), or haptic forces or pressures. In described embodiments, electrical contact, shown as contacts 112 and 114, is made to each of electrodes 102 and 104 in order to use the device as a sensor or an actuator.

As shown in FIG. 1B, in some embodiments, substrate 104 itself is electrically conducting and acts as one of the electrodes of variable capacitor 108. In such an embodiment, electrodes 102 and substrate/electrode 104 can each be implemented as a metal such as gold, silver, chrome, aluminum, or a two-dimensional (2-D) material such as single-layer graphene or multi-layer graphene, or a conductive polymer such as silver nano-wire embedded parylene, graphene embedded parylene, conductive highly-doped silicon, or conducting oxides such as indium tin oxide (ITO), indium zinc oxide (IZO), and aluminum zinc oxide (AZO).

Thus, as shown in FIG. 1B, in described embodiments, a variable capacitance transducer 108 is formed by a variable-capacitance electromechanical structure 100 having a 2-D array 106 of silica micro/nano shells 110. While shown in FIG. 1B as being laterally disposed (e.g., silica shells 110 are disposed along the x-axis and extend along the z-axis), array 106 may instead be vertically disposed (e.g., disposed along the y-axis and extending along the z-axis), or as described herein, may be a three-dimensional (3-D) array. Silica shells 110 are disposed between two conductive electrodes, 102 and 104. In some embodiments, electrode 104 may also act as a substrate for the electromechanical structure 100. Silica shell array 106 is employed as a dielectric spacer layer that can be stressed/loaded to increase or decrease the distance between in electrodes 102 and 104, thereby forming variable capacitor 108.

In described embodiments, silica shells 110 range from nanometers to tens of microns in diameter (e.g., d₂ and d₃) in an unstressed state. For example, in described embodiments, silica shells 110 may have diameters as thin 2 nm and upwards depending on a desired porosity, void fraction, or volume of shells 110. Shell volume, shell wall thickness, and material composition of the shell can be adjusted to determine an elastic modulus, stroke length, or displacement of the shell array. Shell wall thickness, shell void volume, and total shell volume may have strong correlations to the stiffness and stroke length of the shell array. Silica shells 110 are electrically non-conductive and/or insulating. In some embodiments, silica shells 110 enclose air within their volume. In other embodiments, silica shells 110 may enclose other dielectric materials such as various polymers or fluids within their volume. As described herein, the volume of these silica shells refers to the space enclosed by the silica shell walls formed by array 106.

While shown herein as having a generally circular cross-section and substantially equal radii along all axes, silica shells 110 may take on other shapes, or the circular cross-section may not necessarily have the same radius along all axes. In some embodiments, shells 110 may be spherical, cylindrical with a circular or elliptical cross-section, or a disc. Additionally, while shown herein as being substantially uniform in size and shape, the plurality of silica shells 110 may instead by irregularly sized and/or shaped. In some embodiments, the cross-section of silica shells 110 may be generally oblong or oval, for example having a radius in one axis on the order of tens of nanometers, and a radius in another axis that is substantially of the same order of magnitude, but not necessarily equal (e.g., d₂ and d₃ are not necessarily equal in an unstressed state of silica shells 110). Furthermore, as noted herein, the figures are not drawn to scale.

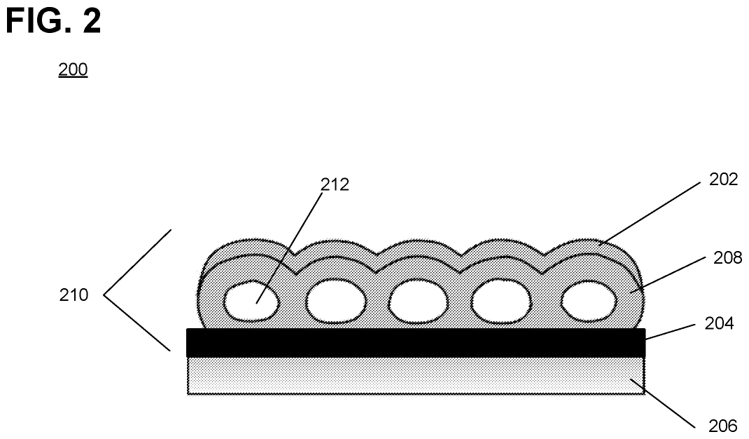

FIG. 2 shows a cross-sectional view of a similar variable-capacitance electromechanical structure as shown in FIG. 1B, but where one electrode is distinct from the underlying substrate. Similarly as shown in FIG. 1B, silica shell array 208 of electromechanical structure 200 acts as a dielectric spacer layer in a variable capacitor 210 formed by electrodes 202 and 204. As shown in FIG. 2, variable-capacitance electromechanical structure 200 may include a two-dimensional lateral array 208 of a plurality of silica micro/nano shells 212 disposed between two conductive electrodes 202 and 204. Electrode 204 is disposed on substrate 206. Thus, as shown in FIG. 2, electrode 204 may be distinct from substrate 206.

In some embodiments, electrode 204 may be implemented as a conductive coating disposed on substrate 206. Substrate 206 may be implemented as an insulating or a semi-conducting material such glass, quartz, silicon, or plastic such as polyethylene terephthalate (PET), polyvinyl chloride (PVC), polymethyl methacrylate (PMMA), and other similar materials. The conductive thin film coating forming electrode 204 may be implemented as metals including gold, silver, aluminum, and chrome, or may be implemented as conductive oxides such as ITO, AZO, or IZO. The conductive thin film coating of electrode 204 may further be implemented as 2-D materials such as graphene, or implanted layers such as highly doped silicon, or coatings of doped polymers such as nano-wire-embedded parylene and graphene-embedded parylene.

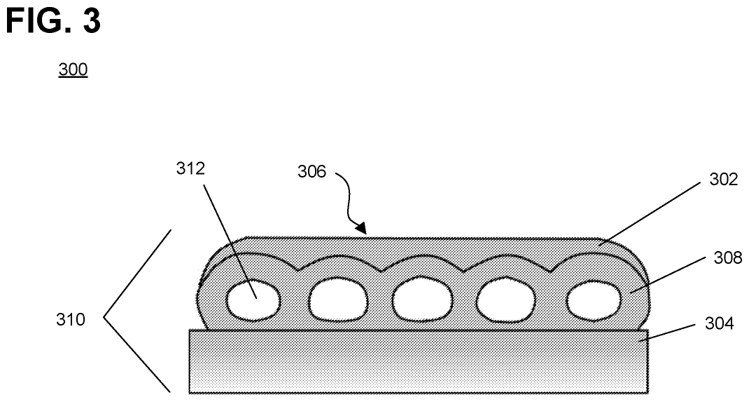

As shown in FIGS. 1B and 2, in some embodiments, a “top” electrode (e.g., electrode 102 of FIG. 1B or electrode 202 of FIG. 2) may generally take on the contour of the underlying shape of the silica shell array (e.g., array 106 of FIG. 1B or array 208 of FIG. 2). As shown in FIGS. 1B and 2, electrodes 102 and 202 may take on the generally arced or uneven or undulating contour of array 106 and 208, respectively, due to the generally circular shape of the silica shells 110 and 212, respectively. As shown in FIG. 3, in other embodiments, electrode 302 might be planarized along a plane or a set of two axes, shown as sheen on surface 306. This might allow electromechanical structure 300 to be employed, for example, in optical applications. Thus, as shown, electrode 302 has a flat surface 306 and does not take on the contour of the shape of array 308 and/or silica shells 312. While shown in FIG. 3 as employing the combined electrode and substrate 304 such as shown in FIG. 1B, electromechanical structure 300 could also employ a distinct substrate and a distinct electrode such as shown in FIG. 2.

In some embodiments, the electromechanical structure (e.g., electromechanical structure 100 of FIG. 1B, electromechanical structure 200 of FIG. 2, or electromechanical structure 300 of FIG. 3) may be composed of materials that are optically transparent in one or more selected spectral bands such as infra-red (IR), visible light, or ultraviolet (UV), providing an electromechanical sensor or actuator that is transparent and can be used, for example, in optical applications. For example, in some embodiments, a transparent “top” electrode (e.g., electrode 102 of FIG. 1B, 202 of FIG. 2, or 302 of FIG. 3) may be implemented using materials such as ITO, IZO, AZO, graphene, doped polymers, silver nano-wire doped parylene (or other polymer), graphene doped parylene (or other polymer), or conductive polymers. In some embodiments, a transparent “bottom” electrode (e.g., electrode 104 of FIG. 1B, 206 of FIG. 2, or 304 of FIG. 3) may be implemented using graphene, ITO, IZO, AZO, or other metal oxides. In some embodiments, a transparent substrate (e.g., substrate 104 of FIG. 1B, 204 of FIG. 2, or 304 of FIG. 3) may be implemented using materials such as glass, quartz, fused quartz, or rigid or flexible polymeric substrates such as PET or ITO-coated PET (ITO-PET). The arrays of silica shells (e.g., array 106 of FIG. 1B, 208 of FIG. 2, or 308 of FIG. 3) may be inherently transparent, depending on any polymers or fluids contained within their volume.

As described herein, employing compliant silica shells enables an electromechanical device to respond to a variety of forces. For example, in embodiments where the electromechanical device is used as a sensor, the compression and relaxation of the dielectric layer silica shells due to externally applied force(s) causes a change in capacitance of the variable capacitor that can generate an electrical signal indicative of the magnitude of the applied force(s). In embodiments where the electromechanical device is used as an actuator, the silica shells can be repetitively compressed and relaxed using electrostatic forces by applying an electric field using a voltage or a current source connected to the electrodes.

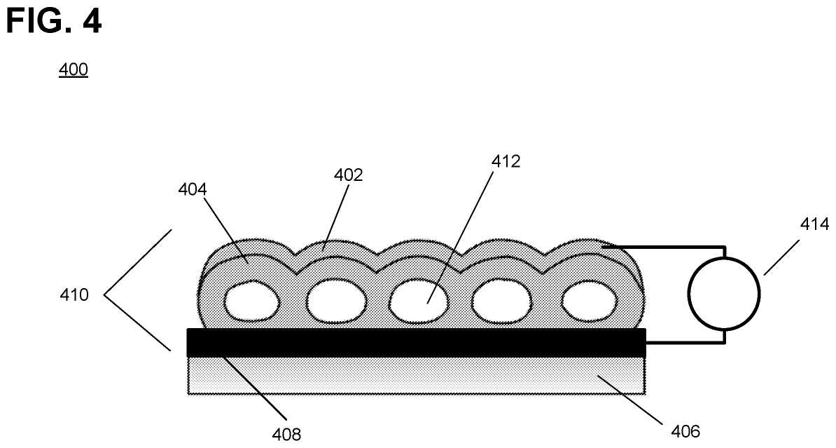

FIG. 4 shows an illustrative electromechanical actuator 400 employing an array of silica shells. Electromechanical actuator 400 can be employed in applications when the rate of the applied dynamic force is varied from static (DC) to ultrasonic frequencies (MHz). In the illustrative embodiment shown in FIG. 4, a source 414 is coupled to electrodes 402 and 408. Source 414 might be implemented as a DC voltage source, an AC voltage source, a DC current source, an AC current source, an RF source, or combinations thereof. When an electric field is applied between the electrodes 402 and 408, attractive electrostatic forces may cause electrodes 402 and 408 to move toward one another (e.g., one or both of electrodes 402 and 408 move), thereby compressing the array 404 of compliant silica shells 412. In some embodiments, “top” electrode 402 is movable, while “bottom” electrode 408 remains in a static position fixed to substrate 406. When no electric field is applied, the absence of electrostatic forces causes one or both of electrodes 402 and 408 to return to their original positions, thereby relaxing the compliant silica shells.

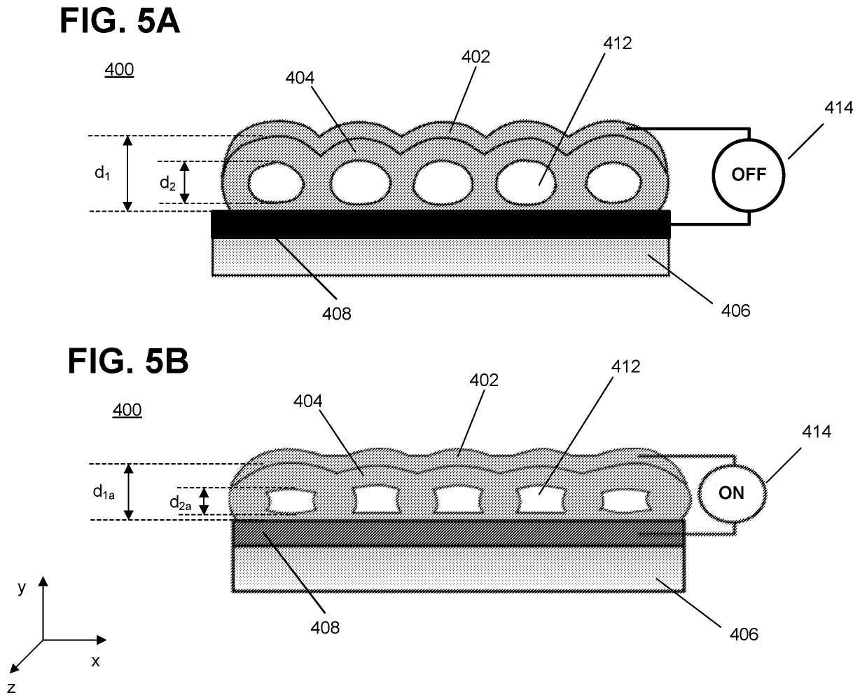

For example, FIG. 5A shows an “OFF” state of electromechanical actuator 400. As shown in FIG. 5A, when a stimulus (e.g., an electric field) is not applied by source 414 between the two electrodes 402 and 408 (e.g., source 414 is “off”), the absence of electrostatic forces allows electrode 402 to remain in its original position, such that silica shells 412 and array 404 are in a relaxed or non-deformed state, and electrodes 402 and 408 are at their greatest distance from one another (e.g., d₁ and d₂ are the greatest values). As shown in FIG. 5B, when a stimulus (e.g., an electric field) is applied by source 414 between the two electrodes 402 and 408 (e.g., source 414 is “on”), attractive electrostatic forces cause electrode 402 to move towards electrode 408, thereby compressing array 404 of compliant silica shells 412 (e.g., d₁ₐ and d₂ₐ are less than d₁ and d₂) by an amount that is correlated to the magnitude of the applied stimulus (e.g., d₁ and d₂ are variable based upon the magnitude of a stimulus, such as a voltage, applied by source 414 to electrodes 402 and 408). For example, in described embodiments the displacement may be proportional to the square of the voltage applied to the electrodes (e.g., the applied force is proportional to the square of the applied voltage).

Thus, as shown in FIGS. 5, 5A, and 5B, described embodiments provide a variable-capacitance electromechanical structure that can be employed as an actuator. Electromechanical actuator 400 is operable between two states corresponding to the presence or absence of a stimulus such as an electric field that can compress or relax compliant micro/nano shell array 404. As described, in an “off” state (e.g., source 414 is off), electromechanical actuator 400 may be in a state where the physical distance between electrodes 402 and 408 is at a relative maximum value (e.g., as shown in FIG. 5A). As a stimulus is applied by source 414 to electrodes 402 and 408, electrode 402 may move along the y-axis toward electrode 408 corresponding to the magnitude of the applied stimulus, until reaching a desired or controlled compression point of array 404 (e.g., the “on” state). In described embodiments, the magnitude of the applied stimulus may be controllably varied using a DC source or signal, an AC source or signal, or a combination of AC and DC sources or signals.

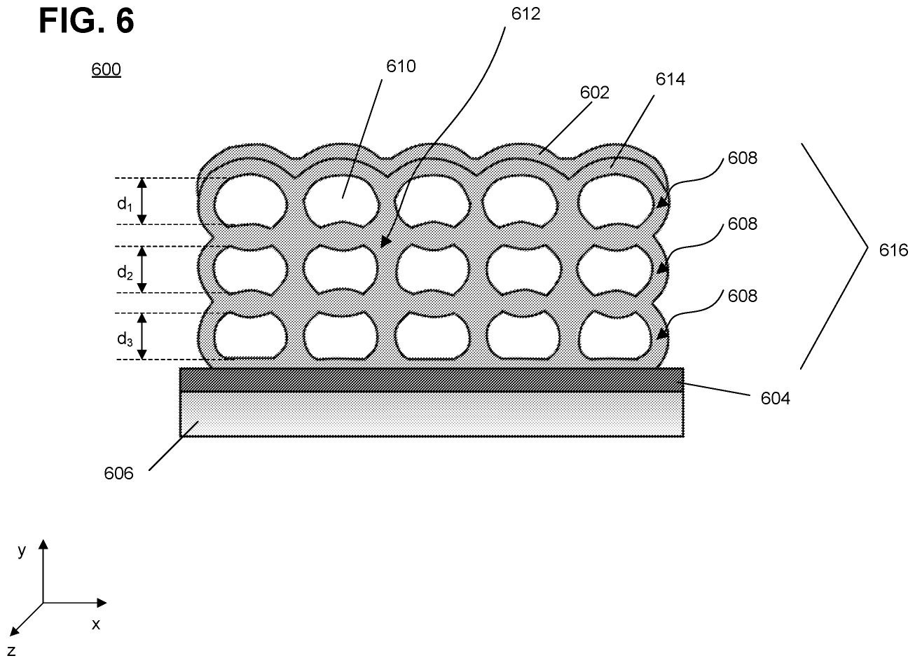

As shown in FIG. 6, in some embodiments, the micro/nano silica shells can be arrayed in three dimensions to further control and vary the properties of the dielectric spacer layer 612, and therefore, of the overall electromechanical structure 600. For example, physical properties of dielectric spacer layer 612 such as stiffness, compliance, thickness, etc., can be varied by adding or removing shell array layers 608 from silica shell array 614. Stiffness of the array may be indicated, for example, by the effective Young's modulus of the array, the Poisson's ratio of the array, an effective flexural rigidity of the array, or an effective spring constant of the array.

Varying the physical properties of dielectric spacer layer 612 can in turn vary properties of the overall electromechanical structure 600, such as the achievable actuation deflection or stroke length of the electrodes (e.g., the variable distance between “top” electrode 602 and “bottom” electrode 604), the capacitance value range of variable capacitor 616, the achievable spectral sensitivity or responsivity tuning of electromechanical structure 600, the achievable signal-to-noise ratio (SNR) of electromechanical structure 600, and other properties. For example, the spectral sensitivity and/or SNR may be selected in a desired frequency range, such as acoustic frequencies including audio and/or ultrasound frequencies, optical frequencies, or both. Furthermore, silica shell array 614 might include shells 610 with varying shell size or diameter (e.g., in a relaxed state, d₁, d₂, and d₃ may or may not be substantially equal), varying shell volume, varying shell shape, and varying shell wall thickness to achieve different properties of electromechanical structure 600.

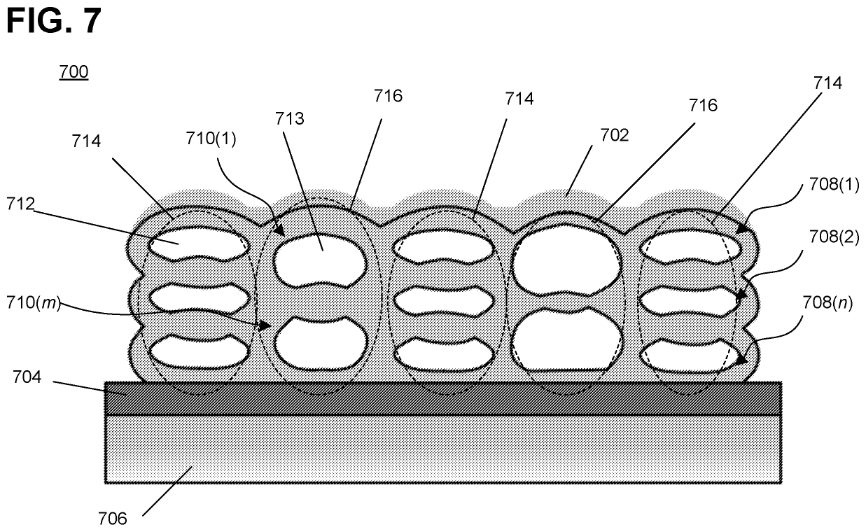

FIG. 7 shows an illustrative embodiment of an electromechanical structure 700 having silica shells of different combinations of shell size (diameter or characteristic length), shape, and shell wall thickness arranged into regions, shown as one or more first regions 714 and one or more second regions 716. As shown in FIG. 7, the regions 714 and 716 may be fabricated on the same substrate 706 and disposed between the same electrodes 702 and 704. As shown in FIG. 7, an illustrative first region 714 may include multiple layers of silica shell arrays, shown as array layers 708(1)-708(n), where n is an integer greater than 1 (shown as n=3 in the illustrative embodiment shown in FIG. 7). An illustrative second region 716 may also include multiple layers of silica shell arrays, shown as array layers 710(1)-710(m), where m is an integer greater than 1 (shown as m=2 in the illustrative embodiment shown in FIG. 7). In described embodiments, n and m may or may not be equal. Further, although individual array layers (e.g., layers 708(1)-708(n) or layers 710(1)-710(m)) are shown in FIG. 7 as including one silica shell per layer, shown generally as silica shells 712 and 713 respectively, various array layers 708 and/or 710 may include multiple shells, for example as described herein in regard to FIGS. 1-6.

As shown in FIG. 7, first regions 714 may include multiple layers 708 of silica shells 712. Similarly, second regions 716 may include multiple layers 710 of silica shells 713. As shown in the illustrative embodiment of FIG. 7, shells 712 for all the layers 708 may be of generally the same shell wall thickness, shell volume, and shell shape, and shells 713 for all the layers 710 may be of generally the same shell wall thickness, shell volume, and shell shape. As shown in FIG. 7, shells 712 and 713 may vary from each other in one or more of shell wall thickness, shell volume, and shell shape. Thus, regions 714 and 716 might achieve different mechanical properties such as stiffness of the dielectric layer in the respective regions, thereby varying properties of electromechanical structure 700 such as spatially-varying actuation stroke of the top electrode (e.g., electrode 702), localized spectral sensitivity or responsivity of electromechanical structure 700, improved signal-to-noise ratio of electromechanical structure 700, and so forth. Although shown in FIG. 7 as single electrodes 702 and 704, in some embodiments, the electrodes may be segmented into multiple top electrodes 702 and/or multiple bottom electrodes 704 on a single substrate 706. Each of the electrodes may be individually addressed with separate electrical contacts for each electrode segment.

Although shown for clarity as two types of regions 714 and 716 and five total regions in the illustrative embodiment of FIG. 7, any number of region types and any number of total regions may be employed based on the size of substrate 706. Furthermore, although shown in FIG. 7 as each region 714 employing shells 712 having substantially similar shell wall thickness, shell volume, and shell shape in each layer 708, other embodiments are not so limited, and the properties of shells 712 might vary across one or more of the layers 708. Similarly, although shown in FIG. 7 as each region 716 employing shells 713 having substantially similar shell wall thickness, shell volume, and shell shape in each layer 710, other embodiments are not so limited, and the properties of shells 713 might vary across one or more of the layers 710.

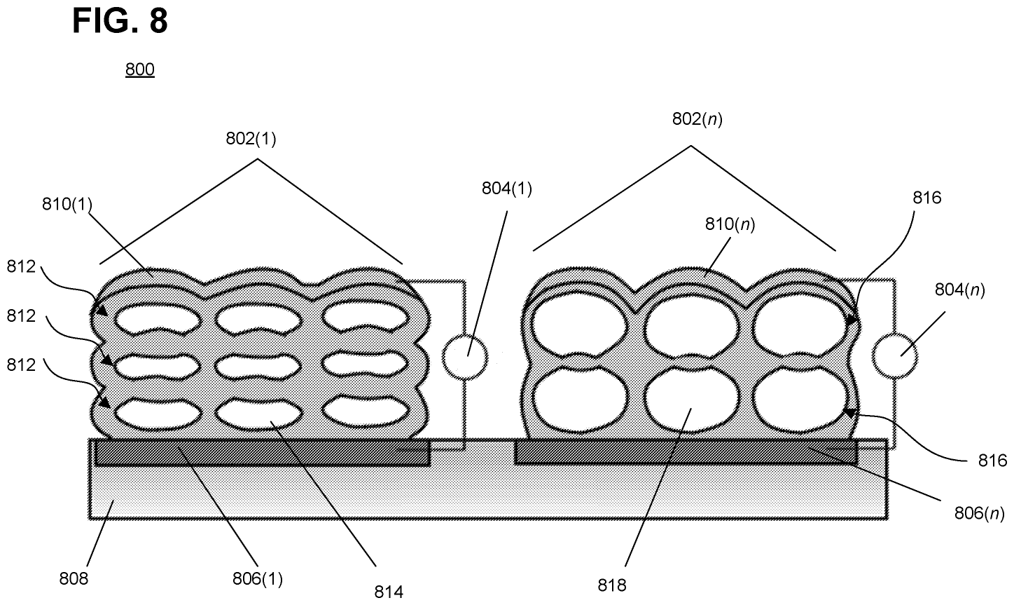

FIG. 8 shows an illustrative embodiment of an electromechanical structure 800 having silica shells of different combinations of shell size (diameter or characteristic length), shape, and thickness arranged into regions, shown as first region 802(1) and second region 802(n), where n is an integer greater than 1 (shown as n=2 in the illustrative embodiment shown in FIG. 8). As shown in FIG. 8, the regions 802(1)-802(n) may be fabricated on separate “bottom” electrodes, shown as electrodes 806(1)-806(n) above a substrate 808, and disposed between separate “top” electrodes, shown as electrodes 810(1)-810(n). Although shown as two regions in FIG. 8 for clarity, any number of regions may be employed. While shown in FIG. 8 as having a 1:1 ratio of regions 802 to corresponding electrodes 806 and 810, other embodiments may employ varying numbers of regions 802 disposed between electrodes 806 and 810, such as shown in FIG. 7.

As shown in FIG. 8, the various regions 802(1)-802(n) may include silica shells of different combinations of shell size (diameter or characteristic length), shape, and thickness. As shown in FIG. 8, and similarly as described in regard to FIG. 7, an illustrative first region 802(1) may include multiple layers of silica shell arrays, shown as array layers 812. An illustrative second region 802(n) may also include multiple layers of silica shell arrays, shown as array layers 816. Further, although shown in FIG. 8 as each array layer 812 and 816 including three silica shells, shown generally as silica shells 814 and 818 respectively, layers 812 and/or 816 may include any number of one or more shells, for example as described herein in regard to FIGS. 1-7.

As shown in FIG. 8, first region 802(1) may include multiple layers 812 of silica shells 814. Similarly, second region 802(n) may include multiple layers 816 of silica shells 818. As shown in the illustrative embodiment of FIG. 8, shells 814 for the layers 812 in first region 802(1) may be of generally the same shell wall thickness, shell volume, and shell shape, and shells 818 for the layers 816 in second region 802(n) may be of generally the same shell wall thickness, shell volume, and shell shape. In some embodiments, shells 814 in first region 802(1) and shells 818 in second region 802(n) may vary from each other in one or more of shell wall thickness, shell volume, and shell shape. Thus, first region 802(1) and second region 802(n) might achieve different mechanical properties such as stiffness of the dielectric layer in the respective regions, thereby varying properties of electromechanical structure 800 across the regions, such as spatially-varying actuation stroke of the top electrodes (e.g., electrodes 810(1)-810(n)), localized spectral sensitivity or responsivity of electromechanical structure 800, spatially-varying signal-to-noise ratio of electromechanical structure 800, and so forth.

Furthermore, although shown in FIG. 8 as each region 802(1)-802(n) employing shells (e.g., 814, 818) having substantially similar shell wall thickness, shell volume, and shell shape respectively, other embodiments are not so limited, and the properties of the shells in each region 802(1)-802(n) might vary across one or more of the layers in each region.

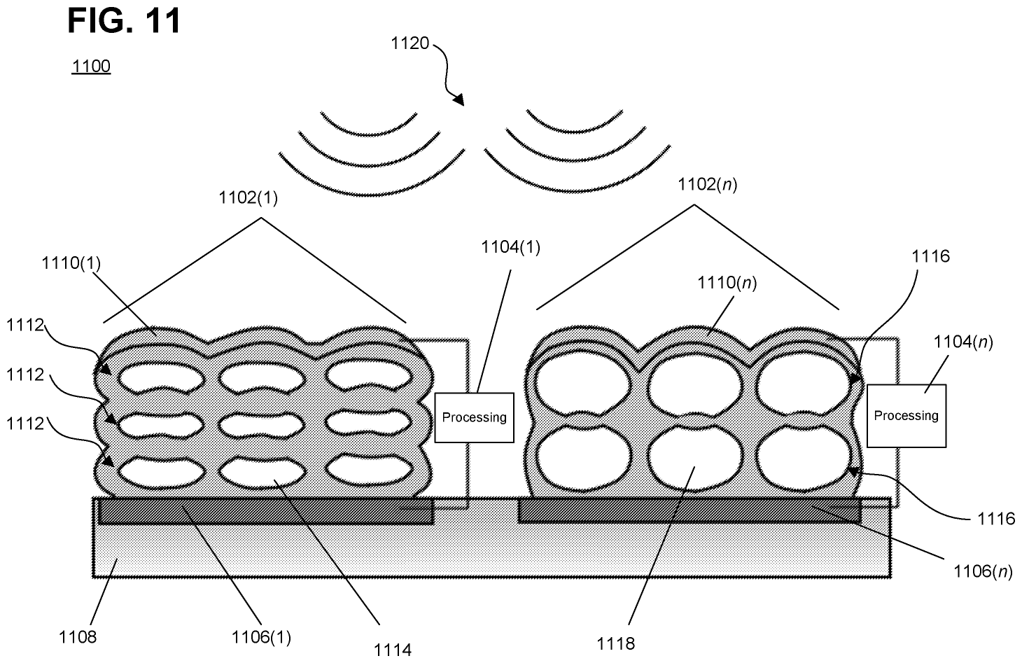

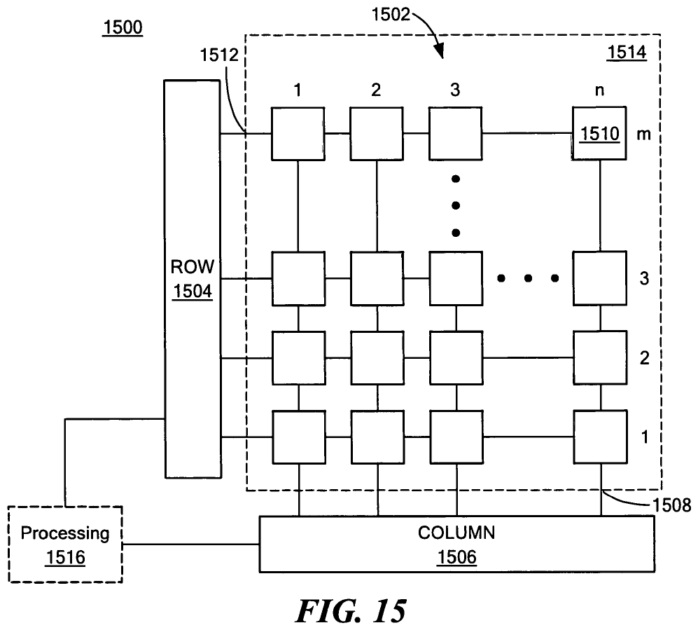

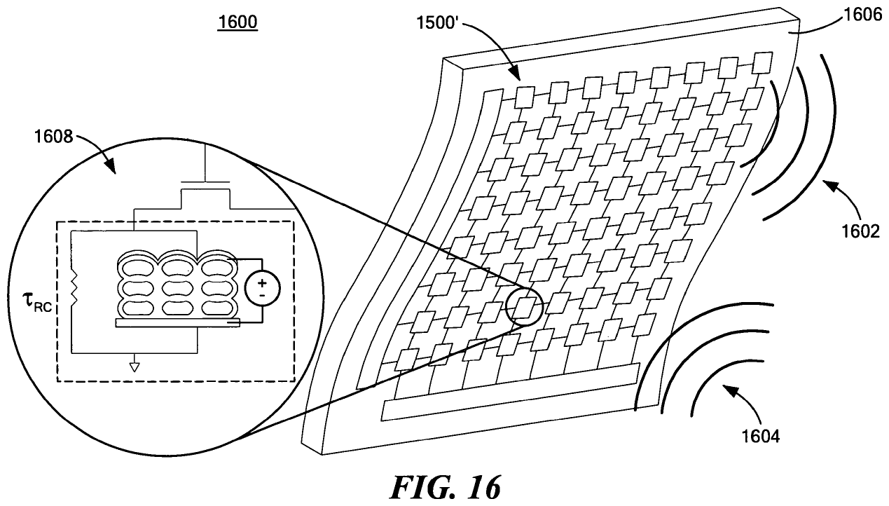

Thus, as shown in FIG. 8, embodiments of variable-capacitance electromechanical structure 800 includes multiple regions (e.g., 802(1)-802(n)) having arrays (e.g., 812, 816) of micro/nano shells (e.g., 814, 818) disposed between two conductive electrodes (e.g., 810, 806). The arrays (e.g., 812, 816) of silica shells in each region may be of varying shell wall thickness, shell volume, and shell shape, where the arrays can be formed or fabricated atop one another (e.g., in an array stack). In some embodiments, each region 802(1)-802(n) may include shells of a substantially similar set of shell parameters under a single top electrode which, in turn, allows that region to be addressed or actuated independently of other regions (e.g., region 802(1) may be addressed or actuated independently of region 802(n), etc.). The various regions 802(1)-802(n) may have different mechanical properties with respect to one another and multiple such regions with different mechanical properties on a single substrate (e.g., 808) may be employed in dynamic sensors or vibrational-energy harvesting panes, for example as shown in FIG. 11, or may be employed in phased array surfaces that are capable of functional multiplexing, for example as shown in FIGS. 15 and 16.

As described herein, some embodiments of the electromechanical devices described herein may be employed in acoustic systems, for example microphones, ultrasound receivers, acoustic filter banks, pressure sensors, and the like. Other embodiments of the electromechanical devices described herein may be employed in actuators, speakers, ultrasound transmitters, or haptic sensors. Additionally, various embodiments may be employed together, for example in phased arrays of sensors and actuators.

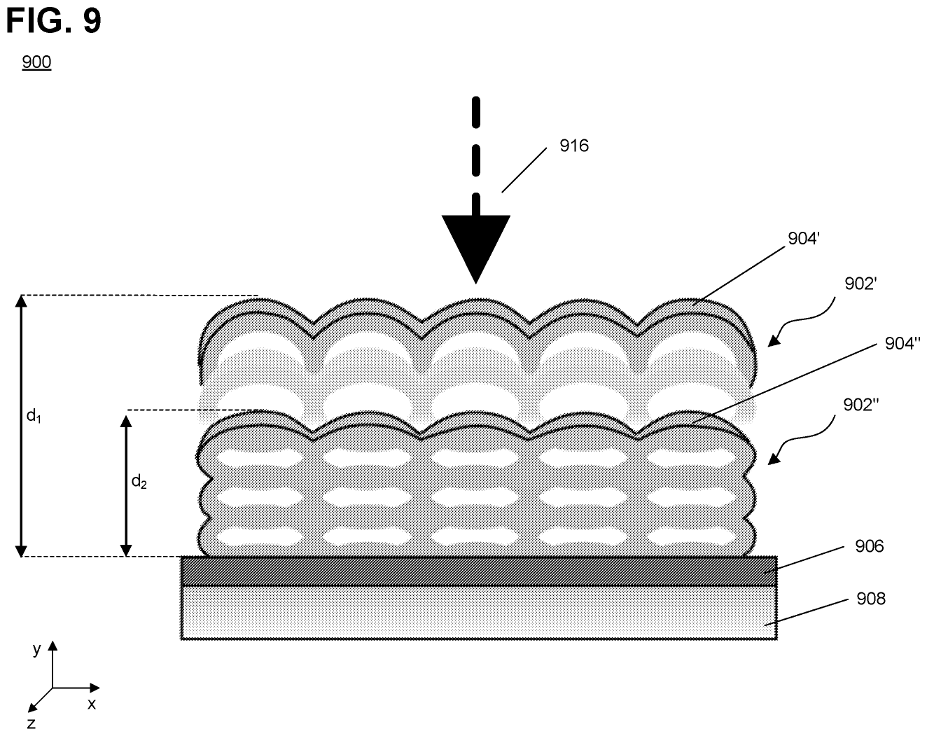

FIG. 9 shows an illustrative embodiment of electromechanical structure 900 consisting of silica shells arrayed in three dimensions between two opposing electrical conductors (for example, similarly as electromechanical structure 600 shown in FIG. 6). As shown in FIG. 9, electromechanical structure 900 may be under electrostatic, acoustic, haptic, or pneumatic actuation, indicated as incident force 916. When force 916 is applied on electromechanical structure 900, the relaxed compliant silica shells 902′ are compressed in proportion to the intensity of the applied force 916, shown as compressed compliant silica shells 902″. For example, as shown, when electromechanical structure 900 is in a relaxed position (e.g., force 916 is not present, or is not sufficient to compress the relaxed compliant silica shells 902′ from a maximum thickness), the array of relaxed compliant silica shells 902′ may have a thickness d₁, such that “top” electrode 904′ is at a maximum distance from “bottom” electrode 906. When electromechanical structure 900 is in a compressed position (e.g., force 916 is sufficient to achieve compression of the compressed compliant silica shells 902″), the array of compressed compliant silica shells 902″ may have a thickness d₂, where d₂ is less than d₁, such that “top” electrode 904″ is at a smaller distance from “bottom” electrode 906 relative to the distance that is present in the relaxed position. Further, in proportion to the intensity of applied force 916, the array of compliant silica shells may have a corresponding thickness between d₁ (minimum compression, maximum thickness shown as 902′) and d₂ (maximum compression, minimum thickness shown as 902″). When force 916 is decreased and/or removed, compressed compliant silica shells 902″ may relax back to their uncompressed state (e.g., relaxed compliant silica shells 902′). This device behavior under incident forces or actuation is similar to that of a device with just a one-dimensional or a two-dimensional array of silica shells as its dielectric spacer layer, such as shown in FIGS. 5A and 5B.

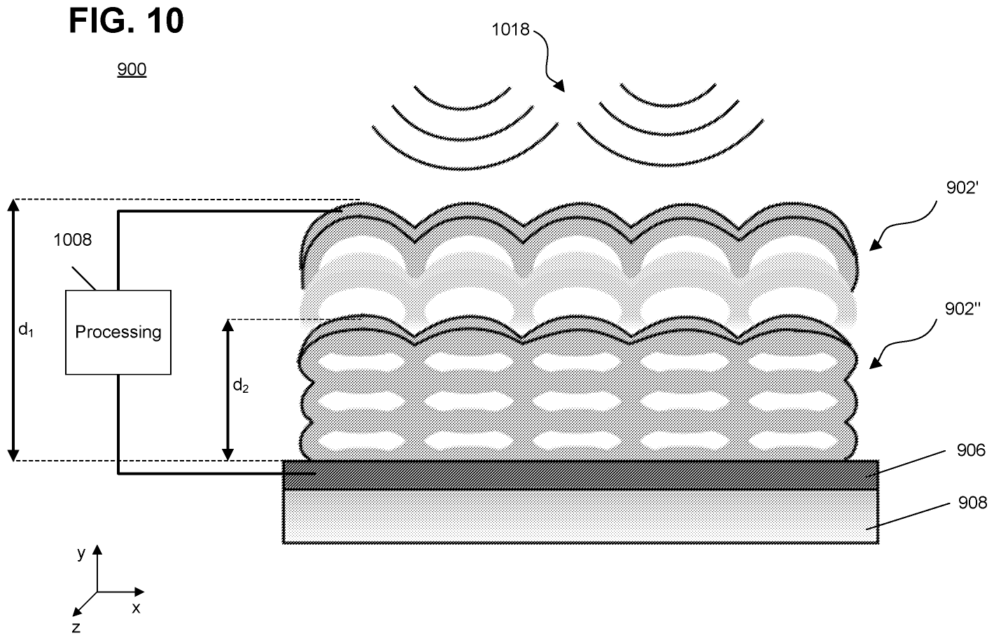

As described herein, mechanical compliance and elastic deformability of the dielectric layer of one or more arrays of silica shells between conducting electrodes enables a MEMS/NEMS electromechanical structure to respond to acoustic or pneumatic actuation. Pressure applied by an incident sound wave or pressure wave causes the compression and relaxation of the device dielectric layer, thus changing the distance between the electrodes. As shown in FIG. 10, this changing inter-electrode distance, for example of an electromechanical structure 900 such as shown in FIG. 9, results in a varying electrical capacitance that can be sensed and further processed and recorded for example by a processing circuit 1008. Processing circuit 1008 may be coupled to one or both of electrodes 904 and 906 to receive a sensed signal corresponding to the compression of compliant silica shells 902 and, thus, the position or displacement of “top” electrode 904. In some embodiments, processing circuit 1008 may amplify the received signal, and further process the signal, in order to execute some additional action in response to the sensed signal. In some embodiments, processing circuit 1008 may include biasing circuitry (e.g., such as source 414 of FIG. 4) to adjust a gain or responsivity associated with each structure in the sensor array.

In some embodiments, processing circuit 1008 may be implemented as one or more of complementary metal oxide semiconductor (CMOS) circuitry, application specific integrated circuits (ASICs), microprocessors, or digital signal processors (DSPs). In some embodiments, processing circuit 1008 may be disposed on the same die as the electromechanical structures acting as acoustic sensor(s). As described herein, in some embodiments, substrate 908 may be implemented as a conductive substrate (e.g., substrate 908 also acts as electrode 906), or as a non-conductive substrate coated with a separate electrically conducting film or layer that can be patterned into discrete regions of arbitrary shape and size, allowing each region to be electronically addressed individually (or in groups).

Such a structure could be used to sense sound and/or static and dynamic pressure changes across a broad range of frequencies such as audio (e.g., approximately 20 Hz to approximately 20 kHz) and ultrasound (e.g., approximately 20 kHz to approximately 50 MHz or higher). As such, described embodiments may be employed to implement pressure sensors, microphones, and ultrasound receivers, among other applications, such as shown in FIG. 11.

In some embodiments, acoustic sensor 1100 with pressure, audio, and/or ultrasound sensing functionality may be fabricated on the same substrate (e.g., substrate 1108). A sensitivity of sensor 1100 to acoustic actuation in different frequency ranges may be tuned via the variation of parameters of the dielectric layer's silica shell array (e.g., array layers 1112 and 1116), such as shell size (diameter or characteristic length), shell wall thickness, number of shell layers 1112 or 1116 between opposing electrodes 1110 and 1106, and shell shape (e.g., of shells 1114, 1118). By employing multiple regions of structures (e.g., 1102(1)-1102(n)) employing dielectric layers of arrays of silica shells having different effective mechanical stiffness or compliance, sensor 1100 can tune each region's acoustic sensitivity to a given frequency band. Each region's (e.g., 1102(1)-1102(n)) picked-up signal may be processed (e.g., by one or more processors 1104) to provide a total sensed signal of sensor 1100, and a sensitivity of each region may be controlled electronically via pre-amplifier gain or via an applied electrical bias such as a DC voltage. The sensitivity of each region may also be controlled via an applied mechanical force and/or a pneumatic bias (bias pressure) in an enclosure (not shown) housing sensor 1100. Although shown in FIG. 11 as each region 1102 having a corresponding processing circuit 1104, in some embodiments, one or more central processors (not shown) may receive sensed signals from and provide control signals to one or more of the regions 1102.

Thus, as described herein, some embodiments may employ multiple electromechanical structures (1102(1)-1102(n)) having varying dielectric layer properties in order to implement a sensor array on a substrate that can be multiplexed to increase or decrease the sensitivity of the acoustic sensors in real-time depending on the intensity of the incident acoustic signal. For example, an array of such electromechanical structures with each structure in the array having a different dielectric layer stiffness can be fabricated on the same substrate to implement an acoustic filter bank which filters out noise and undesirable frequencies in real-time while picking-up a desired acoustic signal (e.g., signal 1120) in the desired frequency ranges, such as shown in FIG. 11. The frequency bands of interest can also be controlled in real-time for each region 1102 of the array by the corresponding processing circuit 1104 by electronically adjusting a gain and/or an electrical bias associated with each structure (region) 1102 in the sensor array.

As described herein, embodiments of the various electromechanical structures, such as sensor 1100 of FIG. 11, may be implemented using optically transparent materials for integration of such acoustic sensors atop optical displays in devices such as smartphones, tablets, electronic book (e-book) readers, and wearables such as smart watches and augmented reality/virtual reality (AR/VR) headsets, among other applications.

In conventional implementations for generating sound, for both portable and sedentary/stationary applications, MEMS transducers have not been as favored as piezoceramics or the traditional magnetic/inductive voice coil elements. The latter choices pose significant disadvantages in both the quality of sound produced and the energy needed to produce it. Yet, piezoceramics and voice coil technologies are ubiquitous because displacing volumes of air large enough to produce audible acoustic pressure changes requires significant mechanical displacement which is difficult to attain using micron-thick films of conventional IC material sets deflecting at reasonably low actuation voltages. However, with the combination of device areas larger than standard 8-inch wafers used in conventional MEMS foundries and compliant dielectric spacer layers of silica shell arrays, such technical hurdles can be overcome to implement energy-efficient sound-production actuators with relatively low manufacturing complexity.

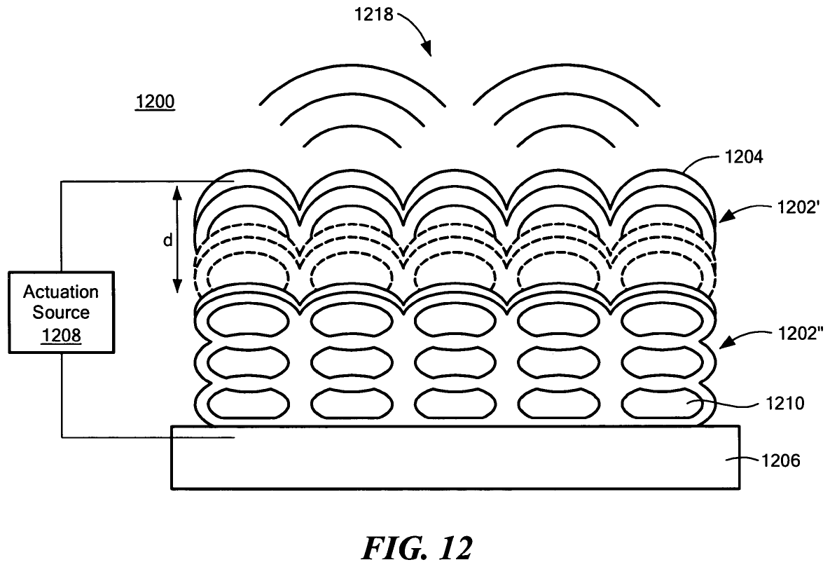

As shown in FIG. 12, some embodiments may be employed to produce sound, for example by employing electromechanical structure 1200 as an actuator or speaker in which an electrical signal (e.g., provided by actuation source 1208) is used to control the displacement of “top” electrode 1204 with respect to a “bottom” electrode (shown in FIG. 12 as being an integrated electrode and substrate 1206, but not so limited, as described herein). The displacement is controlled by varying the electrostatic force applied by source 1208 to the two opposing electrodes 1204 and 1206. The repetitive, time-varying displacement, shown as displacement d, of “top” electrode 1204 in accordance with the electrical signal applied by source 1208 causes displacement of a medium (e.g., air) in contact with the “top” electrode, thus producing vibrations emitted in the form of sound waves or ultrasound waves 1218. When the applied electrical signal varies at audio frequencies (approximately 20 Hz to approximately 20 kHz) or at ultrasonic frequencies (approximately 20 kHz to approximately 50 MHz or higher), the actuator implements an audio speaker or an ultrasonic transmitter, respectively. In described embodiments, source 1208 may include one or more of a DC voltage source for a bias voltage, an AC voltage source, a DC current source, an AC current source, one or more ASICs, a digital-to-analog converter (DAC), an analog-to-digital converter (ADC), one or more amplifiers, boost converters, and/or power sources such as batteries, and other circuitry. In some embodiments, source 1208 may include or otherwise be in electrical communication with a processor providing control signals and/or desired output signals to source 1208, where the desired output signals correspond to a desired audio or ultrasound signal (e.g., signal 1218) to be output from speaker 1200.

Speakers such as speaker 1200 consume minimal electric power due to their inherent capacitive nature and can be used in battery-powered and/or mechanically small devices such as headphones, earphones, hearing-aids, communication headsets, smartphones, tablets, e-book readers, and wearables such as smart watches and augmented reality/virtual reality headsets, etc. Larger areas of speakers such as speaker 1200 can be used as loudspeakers in information displays and entertainment systems, among other applications. When the substrate, the silica shell dielectric layer and the top and bottom electrodes are all optically transparent, such thin form-factor large-area speakers can be integrated atop display screens to provide richer, higher-fidelity and louder sounds, and/or to implement gesture recognition via ultrasonic transmission and sensing, at lower power consumption. Moreover, in embodiments employing a flexible substrate (e.g., substrate 1206), for example using ITO-PET, these large area speakers can be flexible as well, with paper-thin form factors with device thickness ranging from a few microns to hundreds of microns. Further, speaker 1200 may be implemented using optically transparent materials as described herein for integration atop optical displays in devices such as smartphones, tablets, e-book readers, wearables, AR/VR headsets, and other applications.

As described herein, employing dielectric silica shell arrays as described herein allows controlled engineering of the mechanical resonance modes of these electromechanical structures into megahertz (MHz) frequency ranges where the acoustic impedance mismatch between the deflecting “top” electrode and the medium above or surrounding the “top” electrode is minimal. This feature can be exploited to implement energy-efficient, portable, wearable, thin form-factor ultrasound emitters (or transmitters) and receivers. Such ultrasound emitters and receivers may be employed in medical imaging and diagnostics, wrist bands that detect vital signs by measuring and tracking acoustic impedance changes as blood flows through the various blood vessels in the wrist, mechanically-active bandages that can focus ultrasound to controllably deliver drugs such as insulin through the skin-blood barrier, and/or to provide timed, needleless drug delivery via micro-volume ampules that are pumped and/or valved by the deflection of the “top” electrode to push out controlled volumes of drugs through microfluidic wells and channels in the ampules.

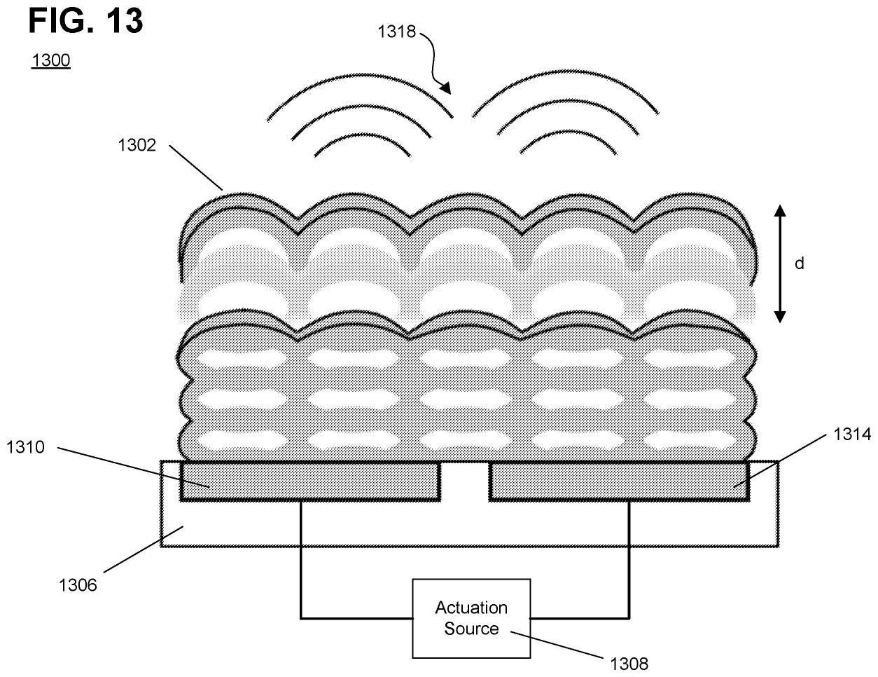

FIG. 13 shows another embodiment of an actuator or speaker structure similar as shown in FIG. 12. As shown in FIG. 13, the “top” electrode 1302 is electrically floating while electromechanical speaker 1300 is electrostatically actuated and displaced distance d by source 1308 applying an electric field between two or more discrete “bottom” electrodes, shown as “bottom” electrodes 1310 and 1314 on substrate 1306. Even though “top” electrode 1302 is electrically floating, electrode 1302 still experiences electrostatic force due to the applied electrical signal and, therefore, it deflects in response to changes in this applied signal's intensity. This deflection or displacement thereby produces acoustic vibrations that are emitted into the surrounding medium (e.g., air) as sound waves 1318. Such an electrical connection scheme eliminates the need to have an electrical contact to “top” electrode 1302, which reduces the complexity associated with making electrical connects/contacts in speaker 1300. Speaker 1300 can be used in similar implementations as speaker 1200.

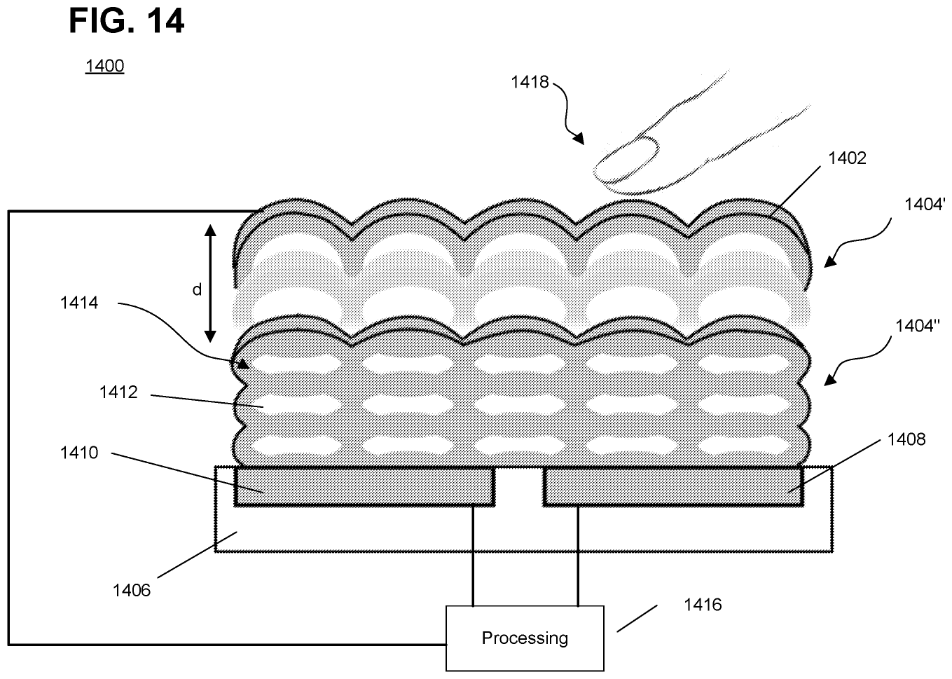

Described embodiments may also be employed in haptic sensors, such as touchscreens, as shown in FIG. 14. Haptic sensor fabrication requires monolithic, large-area fabrication of deflectable elements atop transparent micro- and nano-structured substrates to implement surfaces such as touchscreen keyboards that provide mechanical force feedback and high spatial resolution to enable individually addressable force feedback pixels or regions. Current IC and MEMS fabrication technologies for electrically reconfigurable tactile skins and coatings are limited in their ability to mimic the roughness, friction, and force feedback of different surfaces. However, embodiments of electromechanical structure 1400 may eliminate the need for arrays of suspended and deflectable elements for force feedback. As described herein, electromechanical structure 1400 provides a compliant dielectric layer 1404 of silica shell array(s) (e.g., arrays 1414 of shells 1412). Dielectric layer 1404 provides a robust alternative to suspended plates, cantilevers, and micro-posts for implementing structures that can deliver haptic force feedback and withstand static and dynamic pressures resulting from haptic interactions on surfaces such as touchscreens.

As shown in FIG. 14, electromechanical structure 1400 is implemented as a haptic device for sensing applied pressures, shown as force 1418. Similarly as other embodiments described herein, electromechanical structure 1400 may include one or more arrays 1414 of silica micro/nano shells 1412 disposed between two or more conductive electrodes (e.g., “top” electrode 1402 and one or more “bottom” electrodes, shown as 1408 and 1410). Processing circuit 1416 may measure changes in capacitance and actuate electromechanical structure 1400 for force feedback. As described herein, processing circuit 1416 may be electrically coupled to one or more “top” electrodes 1402 and one or more “bottom” electrodes 1408 and/or 1410 in a manner similar to an active matrix display. Electromechanical structure 1400 may be implemented using optically transparent materials such as described herein to enable integration of the haptic surfaces atop optical displays such as touchscreens.

When pressure is applied to the device during haptic interactions (e.g., force 1418), compliant dielectric spacer layer 1404 compresses and relaxes (shown as displacement d), thus changing the capacitance between one or more pairs of opposing electrodes (e.g., 1402 and 1408, and/or 1402 and 1410). The change in capacitance produces an electric signal that can be sensed and further processed by processing circuit 1416. As described herein, in some embodiments processing circuit 1416 may be embedded in the underlying substrate (e.g., substrate 1406) via CMOS processing prior to electromechanical device fabrication. In addition to sensing haptic pressure and its variations applied to structure 1400, processing circuit 1416 may include device actuation circuitry (e.g., voltage sources, current sources, etc.) to generate haptic force 1418 as feedback to the user (e.g., vibration feedback, etc.). In some embodiments, arrays of such haptic “pixels” or regions may be fabricated on the same substrate (e.g., 1406) and be individually addressed electronically to implement dynamic haptic feedback surfaces that can be individually sensed and/or controlled. Such surfaces could be integrated atop optical displays for haptic feedback keyboards and touchscreens, be used as refreshable braille readers/displays, and as high-resolution fingerprint scanners, among other applications. In some embodiments, a protective coating could also be applied atop the haptic-contact electrode (e.g., “top” electrode 1402) to provide robustness against mechanical stress and strain and/or shearing forces, without changing the electromechanical performance of the haptic device 1400. In some embodiments, the protective coating is optically transparent. Further, in some embodiments, “top” electrode 1402 might be planarized along a plane or a set of two axes, to produce a surface sheen, such as described in regard to FIG. 3. As shown in FIG. 14, “bottom” electrodes 1408 and 1410 may be addressed individually, or in tandem as a single electrode. As described herein, “bottom” electrodes 1408 and 1410 may be implemented as one or more electrodes distinct from the underlying substrate, or as one or more electrically conductive regions integrated into the substrate.

As shown in FIG. 15, multiple electromechanical structures such as described herein may be arranged to form a system 1500 including a phased array of sensors and/or actuators, shown as device array 1502. As shown, device array 1502 may include an n×m array of electromechanical structures 1510, where n and m are integers greater than 1 and may or may not be equal. Each electromechanical structure 1510 may be individually addressable by one or more control lines. As shown in FIG. 15, each electromechanical structure 1510 may be electrically coupled to multiplexed row and column control lines 1512 and 1508, respectively, although other connection arrangements are possible. As shown in FIG. 15, row and column control lines 1512 and 1508 may be coupled to respective multiplexers (e.g., row multiplexer 1504 and column multiplexer 1506), each of which may be in communication with processing circuit 1516 to receive sensed data from, and to provide control signals and output data to, selected ones of structures 1510 via multiplexers 1504 and 1506.

In some embodiments, device array 1502 is disposed on a large area substrate 1514, which may be a rigid surface substrate such as silicon wafers or glass wafers. Such rigid implementations may be employed as rigid panels of transparent, high-fidelity sound producing and sound sensing arrays that can be used as floor-to-ceiling wallpapers, window panels, and even atop electronic displays or in wearable smart textiles. These rigid panels can be employed to implement real-time phased arrays of microphones and speakers that can localize sound sources in space and direct sound to specific spatial regions without obscuring the surfaces upon which they are deployed. Additionally, these panels can potentially implement real-time noise cancellation in specific spatial regions without the use of headphones.

Alternatively, some embodiments may be implemented using flexible polymeric substrates, plastics, etc., to implement flexible sheets such as shown in FIG. 16. Large-area, rigid or flexible, and (optionally) transparent sheets of ultrasonic receivers and transmitters (transducers) have applications such as ultrasound blankets or helmets for imaging and focused therapeutic stimulation. As shown in FIG. 16, system 1500′ such as shown in FIG. 15 may be implemented on a flexible substrate 1606. System 1500′ might be implemented as a transducer capable of sensing applied force(s) 1604, which might be static or dynamic pneumatic pressure(s), audio signal(s), or ultrasound signal(s). The transducer might be capable of generating and emitting output force(s) 1602, which might be static or dynamic pneumatic pressure(s), audio signal(s), or ultrasound signal(s). As shown, each element 1608 of system 1500′ may include a variable-capacitance electromechanical structure such as described herein, for example in regard to FIGS. 1-14. Each element may be individually addressable. The electromechanical structure may be implemented in an electrical circuit having one or more resistors to form a network having an R-C charge and discharge time constant that varies as the variable capacitance of the electromechanical structure varies with applied pressure, as described herein. The variable capacitance and, thus, the variable R-C time constant, can be sensed to determine changes in force(s) applied to a given individually addressable element 1608 (or the overall electromechanical structure), or can be modified (e.g., by applying AC and/or DC signals) to generate output force(s) emitted by a given element 1608. Thus, as described herein, the same electromechanically active surface may be functionally multiplexed to serve as a listening panel for acoustic input of voice commands (digital personal assistant, phone systems, etc.), as a haptic input/output channel, as an ultrasonic gesture recognition input/output interface, and as a large area (optionally transparent) speaker, among other functions. The electromechanically active surface may be implemented using optically transparent materials and may be disposed atop an optical display/screen.

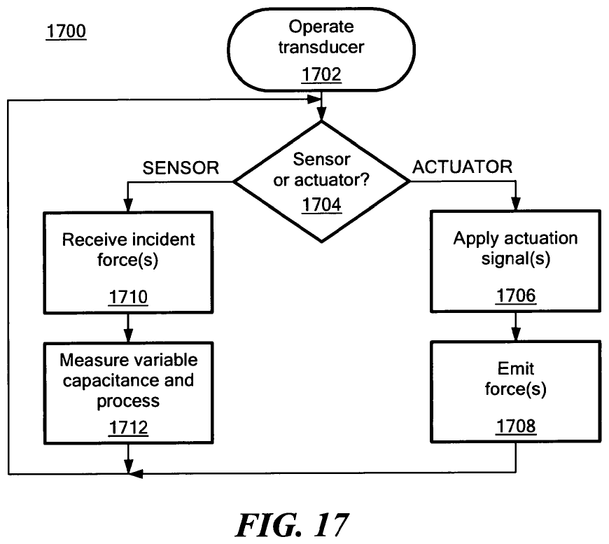

FIG. 17 shows an illustrative process 1700 for operating a variable-capacitance electromechanical structure such as described herein, for example in regard to FIGS. 1-16. At block 1702, a processing circuit begins operation of the electromechanical structure, for example when power is applied.

At block 1704, when the electromechanical structure is operated as a sensor, at block 1710 incident forces are applied to the electromechanical structure. As described herein, applied incident forces may cause a displacement or deflection of a “top” electrode of the electromechanical structure due to the mechanical compliance and elastic deformability of a dielectric array of silica shells between the “top” electrode and a “bottom” electrode. This displacement in turn may cause a capacitance of the electromechanical structure to vary. At block 1712, the variable capacitance may be sensed or measured by the processing circuit. Further processing may associate the measured variable capacitance with a static or time-varying magnitude of the applied incident force. The processing circuit may process this magnitude as a user input action (e.g., in a haptic system), or as a sound signal (e.g., in a microphone system or an ultrasonic receiver system). Process 1700 returns to block 1704 and continues to operate, for example while the system is powered.

At block 1704, when the electromechanical structure is operated as an actuator, at block 1706 actuation signals are applied to the electromechanical structure by the processing circuit. As described herein, applied actuation signals may cause a displacement or deflection of a “top” electrode of the electromechanical structure due to the mechanical compliance and elastic deformability of a dielectric array of silica shells between the “top” electrode and a “bottom” electrode. At block 1708, the displacement may generate an emitted force, such as a vibration (e.g., in a haptic system), as an ultrasonic wave (e.g., in an ultrasonic transmitter system), or as a sound wave (e.g., in an audio speaker system). Process 1700 returns to block 1704 and continues to operate, for example while the system is powered.

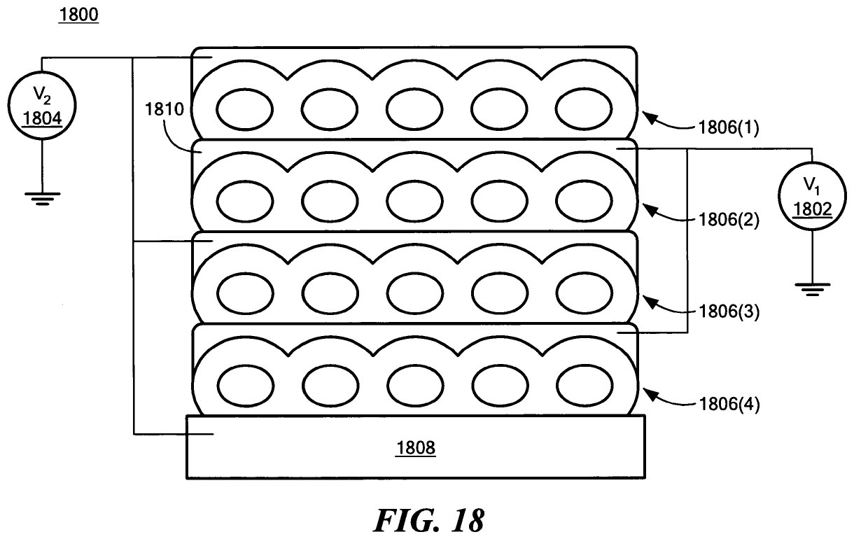

FIG. 18 shows a cross-sectional view of a sensor or actuator 1800 including a plurality of variable-capacitance electromechanical structures 1806(1)-1806(4), generally referred to as 1806. Electromechanical structures 1806 may be implemented upon a common substrate 1808. Substrate 1808 may also act as a “bottom” electrode of a “bottom” structure 1806 (e.g., 1806(4)), or a separate electrode or electrodes may be employed, such as described herein, for example in regard to FIGS. 3 and 4. As shown, the “top” electrode (e.g., 1810) of a lower structure 1806 may also act as the “bottom” electrode of the structure 1806 located above it. Although shown in FIG. 18 as including four electromechanical structures 1806, other numbers of structures may be employed, for example to achieve a specific desired stroke length of overall device 1800. Further, although shown in FIG. 18 as employing structures 1806 having uniform shell arrays, any of the shell geometries shown FIGS. 3, 4, 6, 7, 8, etc. may be employed. Additionally, different shell geometries may be employed between opposing electrode pairs to achieve a desired porosity of each shell array and a specific desired stroke length of device 1800.

Device 1800 may include two or more voltage sources, shown as voltage sources V₁ 1802 and V₂ 1804. In described embodiments, voltage sources V₁ 1802 and V₂ 1804 are distinct voltage sources, and either voltage source may be implemented as 0 Volts (or ground potential). As shown in FIG. 18, voltage sources V₁ 1802 and V₂ 1804 are connected to alternating ones of the electrodes of electromechanical structures 1806. For example, voltage V₁ 1802 may be connected to the “top” electrode of structures 1806(2) and 1806(4), while voltage V₂ 1804 may be connected to the “top” electrode of structures 1806(1) and 1806(3), as well as “bottom” electrode 1808. Although shown as two distinct voltage sources, other numbers of voltage sources may be employed such that each voltage source is coupled to two or more electrodes. Voltage sources V₁ 1802 and V₂ 1804 may be DC sources, AC sources, DC and AC sources, or a combination thereof. In some embodiments, voltage sources V₁ 1802 and V₂ 1804 may be AC sources that output signals of the same amplitude and frequency, but at different phases, or may be varying in one or more of amplitude, frequency, offset, phase with respect to one another, for example as controlled by processing circuit 1516 of FIG. 15.

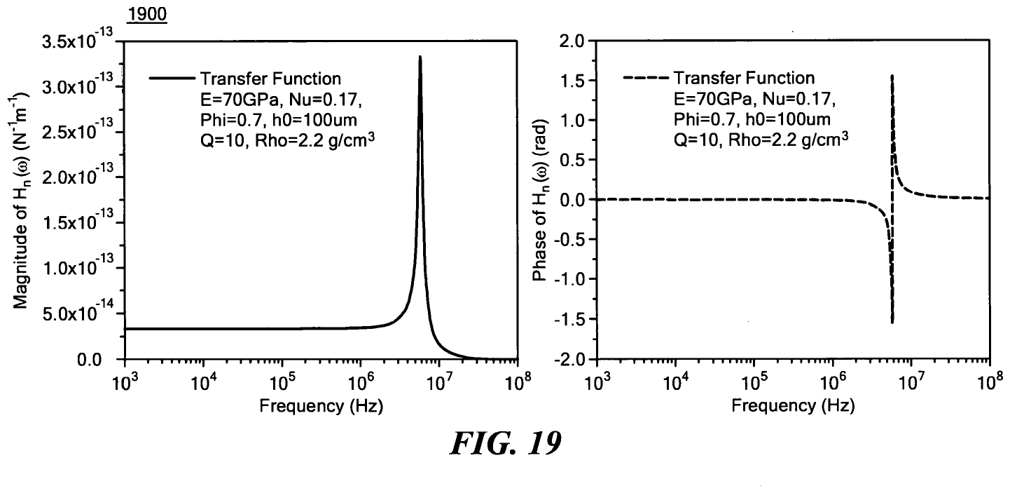

Device 1800 may be employed to achieve a precise resolution of stroke length by individually activating or addressing electrodes of one or more of electromechanical structures 1806(1)-1806(4) to achieve a total stroke length of device 1800 in increments per each layer of electromechanical structures 1806(1)-1806(4). As will be described in regard to FIGS. 19-22, a greater total overall displacement of device 1800 can be achieved from a thin film structure employing multiple layers of electromechanical structures with a smaller thickness but greater effective (or equivalent) stiffness, than can be achieved by employing one structure of the same thickness as the total thickness of structures 1806(1)-1806(4). In other words, employing multiple layers of structures 1806 achieves a greater overall stroke length of device 1800 than employing fewer, but thicker layers. Further, by employing different voltages and/or control signals per layer, fine-tuning of resolution of the displacement may be achieved.

FIG. 19 is a plot showing the magnitude and the phase of the transfer function of the electromechanical response over frequency of an illustrative electromechanical structure having a 100 μm thick shell array (e.g., d₁=100 μm in FIG. 5A, for example). In general, the behavior of the electromechanical structure may be described by the transfer function:

$$H ( ω ) = - \frac{3}{ρ A {h}_{0}} \cdot \frac{1}{{ω}^{2} + \frac{i}{Q} \sqrt{\frac{3 E}{( 1 - {v}^{2} ) ρ {h}_{0}^{2}}} ω - \frac{3 E}{( 1 - {v}^{2} ) ρ {h}_{0}^{2}}}$$

where H(ω) is the transfer function, h₀ is the thickness of the shell array, ω is the angular frequency, ρ is the density of the shell array material, E is the Young's modulus of the shell array material (e.g., silica, etc.), Q is the quality factor representative of the bandwidth of peak resonance, A is the area of the generally out-of-plane deflecting/vibrating/displacing region of the electromechanical structure, i=\sqrt{−1}, and ν is the Poisson's ratio of the shell array material. As shown in FIG. 19, in an illustrative embodiment, h₀ is 100 μm, ρ is 2.2 g/cm³, E is 70 GPa, Q is 10, and ν is 0.17, to achieve a resonance frequency in the range of 5-6 MHz. The displacement amplitude, U (e.g., d₁-d₂) of the shell array may be described by:

$$U ( ω , V ) = {F}_{e} ( V ) H ( ω ) = \frac{{ɛ}_{0} {ɛ}_{r} ( ϕ ) {V}^{2}}{2 {h}_{0}^{2}} {H}_{n} ( ω )$$

where Fₑ is the electrostatic force, h₀ is the array thickness, V is the applied voltage, ε₀ is permittivity of a vacuum or free space, εᵣ(ϕ) is the effective dielectric constant of the shell array, and Hₙ(ω)=AH(ω), where A is the area of the generally out-of-plane deflecting/vibrating/displacing region of the electromechanical structure and H(ω) is the transfer function (shown above).

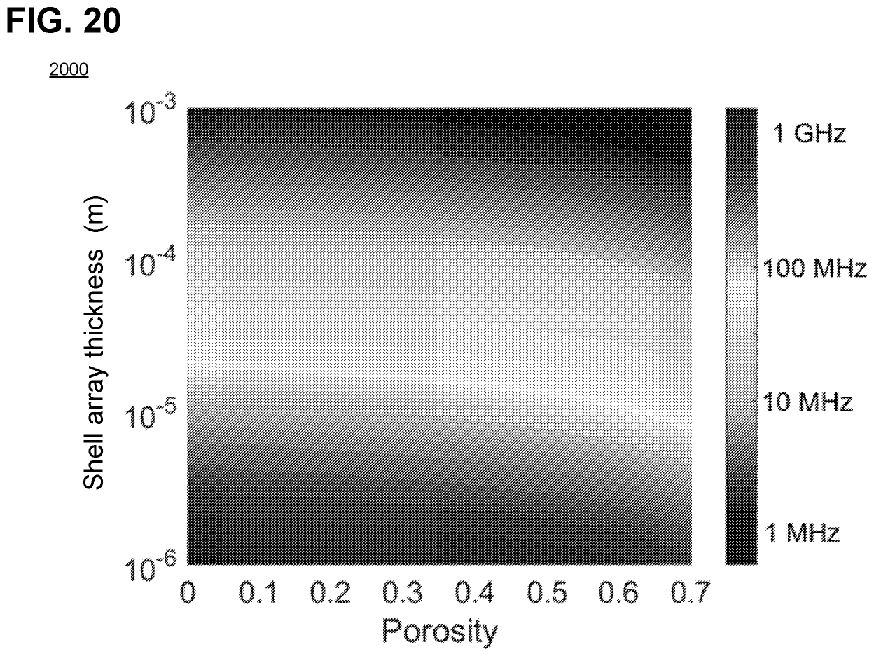

FIG. 20 is a plot showing a relationship between shell array thickness, porosity of the shell array, and resonance frequency of an illustrative embodiment of an electromechanical structure (for example of an electromechanical structure such as shown in FIG. 9). As described herein, porosity of 0.1 indicates that 10% of the shell array is the internal volume of the shell (e.g., air, or a fluid), also referred to as the shell void volume, and 90% of the shell array is the shell wall material. As shown in FIG. 20, as the porosity increases (e.g., as more of the shell array is the internal volume of the shell) for any given thickness of the shell array, the effective stiffness of the shell array decreases, and the resonance frequency decreases. Increasing the shell array thickness at any given porosity, the resonance frequency decreases because the effective mass of the shell array relative to the effective stiffness of the shell array increases. As shown in FIG. 20, in described embodiments the thickness of the shell array (e.g., d₁) may generally vary from several nanometers (e.g., 2 nm) to hundreds of microns or even millimeters, and the porosity may generally vary from 0 to 0.7. The resonance frequency of described embodiments may range from megahertz (MHz) to gigahertz (GHz).

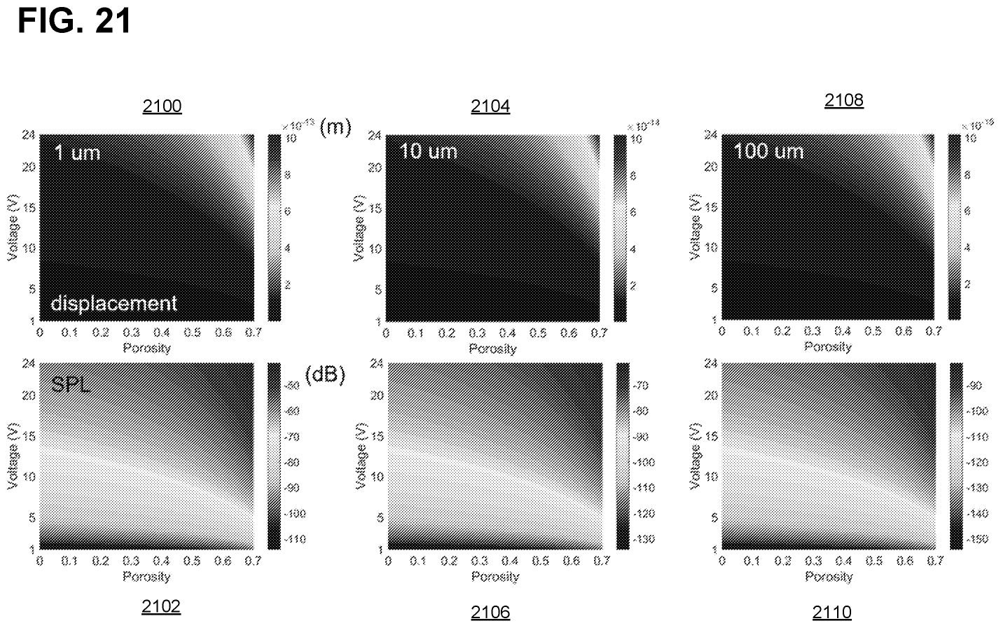

FIG. 21 shows a first series of plots showing a relationship between applied voltage amplitude, porosity of the shell array for silica shells, and displacement amplitude of the electromechanical structure, and a second series of plots showing a relationship between applied voltage amplitude, porosity of the shell array, and sound pressure level (SPL) at a driving signal (or actuation signal) frequency of 1 kHz for shell array thicknesses of 1 μm, 10 μm, and 100 μm.

For example, plots 2100, 2104, and 2108 show displacement as a function of the porosity of the shell array and the applied voltage to the electrodes (for example of an electromechanical structure such as shown in FIG. 9) at a resonant frequency of 1 kHz. In plot 2100, for an embodiment having a shell array thickness (e.g., d₁) of 1 μm, displacement of the shell array may range from 10⁻¹³ m to 10⁻¹² m as voltage and porosity change from 1V to 24V and from 0 to 0.7, respectively. Similarly, in plot 2104, for an embodiment having a shell array thickness (e.g., d₁) of 10 μm, displacement of the shell array may range from 10⁻¹⁴ m to 10⁻¹³ m as voltage and porosity change from 1V to 24V and from 0 to 0.7, respectively, and in plot 2108, for an embodiment having a shell array thickness (e.g., d₁) of 100 μm, displacement of the shell array may range from 10⁻¹⁵ m to 10⁻¹⁴ m as voltage and porosity change from 1V to 24V and from 0 to 0.7, respectively. Thus, as can be seen in plots 2100, 2104, and 2108, as the shell array thickness (e.g., d₁) increases from 1 μm to 10 μm to 100 μm, at any combination of porosity and voltage, a thinner shell array actually achieves higher displacement at 1 kHz. This is because the electric field between electrodes is larger as the distance between electrodes decreases (e.g., as d₁ becomes smaller, the greater the achieved displacement at a given voltage and porosity). Conversely, as the shell array becomes thicker, the achieved displacement becomes smaller at a given voltage and porosity. Thus, a thinner shell array can achieve greater displacement, and therefore also achieve a greater, or louder, sound pressure level.

Plots 2102, 2106, and 2110 show sound pressure level (SPL) as a function of the porosity of the shell array and the amplitude of the applied voltage to the electrodes (for example of an electromechanical structure such as shown in FIG. 9) at a driving signal (or actuation signal) frequency of 1 kHz, at a distance of 0.5 m from the electromechanical structure. In plot 2102, for an embodiment having a shell array thickness (e.g., d₁) of 1 μm, the sound pressure produced by the shell array electromechanical structure may range from approximately −120 dB SPL to approximately −30 dB SPL as voltage and porosity change from 1V to 24V and from 0 to 0.7, respectively. Similarly, in plot 2106, for an embodiment having a shell array thickness (e.g., d₁) of 10 μm, the sound pressure produced by the shell array electromechanical structure may range from approximately −140 dB SPL to approximately −50 dB SPL as voltage and porosity change from 1V to 24V and from 0 to 0.7, respectively, and in plot 2110, for an embodiment having a shell array thickness (e.g., d₁) of 100 μm, the sound pressure produced by the shell array electromechanical structure may range from approximately −160 dB SPL to approximately −70 dB SPL as voltage and porosity change from 1V to 24V and from 0 to 0.7, respectively. Thus, as can be seen in plots 2102, 2106, and 2110, as the shell array thickness (e.g., d₁) increases from 1 μm to 10 μm to 100 μm, at any combination of porosity and voltage, the achievable SPL at 1 kHz decreases, which is a function of the effective compliance and the resulting displacement of the shell array as described in regard to plots 2100, 2104, and 2108.

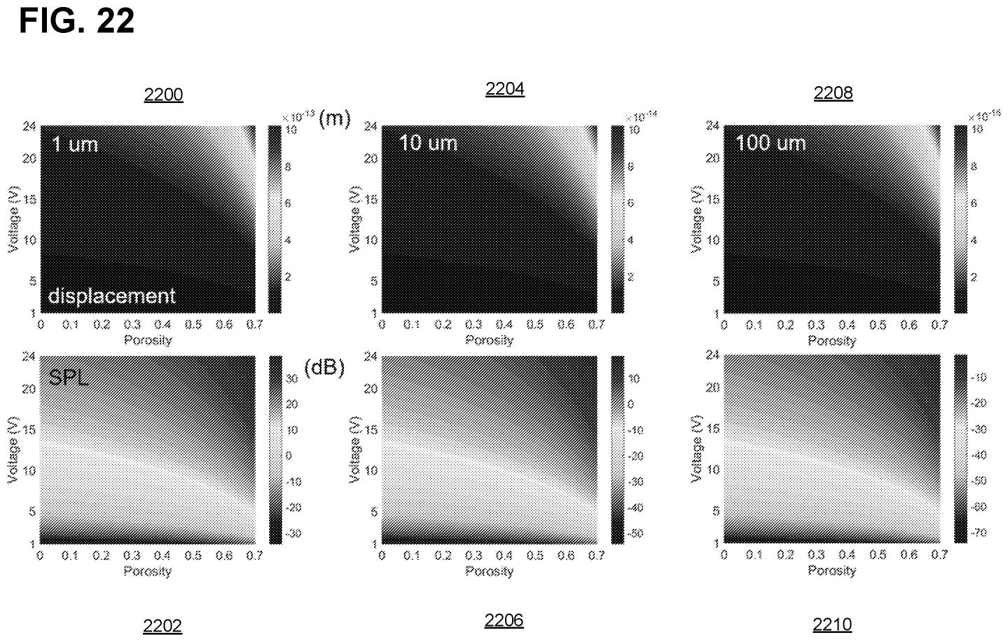

Similarly as FIG. 21, FIG. 22 shows a first series of plots showing a relationship between applied voltage amplitude, porosity of the shell array for silica shells, and displacement amplitude of the electromechanical structure, and a second series of plots showing a relationship between applied voltage amplitude, porosity of the shell array, and sound pressure level (SPL) at driving signal (or actuation signal) frequency of 100 kHz for shell array thicknesses of 1 μm, 10 μm, and 100 μm.

For example, plots 2200, 2204, and 2208 show displacement as a function of the porosity of the shell array and the amplitude of the applied voltage to the electrodes (for example of an electromechanical structure such as shown in FIG. 9) at a driving signal (or actuation signal) frequency of 100 kHz. In plot 2200, for an embodiment having a shell array thickness (e.g., d₁) of 1 μm, displacement of the shell array may range from 10⁻¹³ mh to 10⁻¹² m as voltage and porosity change from 1V to 24V and from 0 to 0.7, respectively. Similarly, in plot 2204, for an embodiment having a shell array thickness (e.g., d₁) of 10 μm, displacement of the shell array may range from 10⁻¹⁴ m to 10⁻¹³ m as voltage and porosity change from 1V to 24V and from 0 to 0.7, respectively, and in plot 2208, for an embodiment having a shell array thickness (e.g., d₁) of 100 μm, displacement of the shell array may range from 10⁻¹⁵ m to 10⁻¹⁴ m as voltage and porosity change from 1V to 24V and from 0 to 0.7, respectively. Thus, as can be seen in plots 2200, 2204, and 2208, as the shell array thickness (e.g., d₁) increases from 1 μm to 10 μm to 100 μm, at any combination of porosity and voltage, a thinner shell array actually achieves higher displacement at 100 kHz, similarly as described in regard to FIG. 21 at 1 kHz.

Plots 2202, 2206, and 2210 show SPL as a function of the porosity of the shell array and the amplitude of the applied voltage to the electrodes (for example of an electromechanical structure such as shown in FIG. 9) at a driving signal (or actuation signal) frequency of 100 kHz, at a distance of 0.5 m from the electromechanical structure. In plot 2202, for an embodiment having a shell array thickness (e.g., d₁) of 1 μm, the sound pressure produced by the shell array electromechanical structure may range from approximately −40 dB SPL to approximately 50 dB SPL as voltage and porosity change from 1V to 24V and from 0 to 0.7, respectively. Similarly, in plot 2206, for an embodiment having a shell array thickness (e.g., d₁) of 10 μm, the sound pressure produced by the shell array electromechanical structure may range from approximately −60 dB SPL to approximately 30 dB SPL as voltage and porosity change from 1V to 24V and from 0 to 0.7, respectively, and in plot 2110, for an embodiment having a shell array thickness (e.g., d₁) of 100 μm, the sound pressure produced by the shell array electromechanical structure may range from approximately −80 dB SPL to approximately 0 dB SPL as voltage and porosity change from 1V to 24V and from 0 to 0.7, respectively. Thus, as can be seen in plots 2202, 2206, and 2210, as the shell array thickness (e.g., d₁) increases from 1 μm to 10 μm to 100 μm, at any combination of porosity and voltage, the achievable SPL at 100 kHz decreases, which is a function of the effective compliance and the resulting displacement of the shell array similarly as described in regard to FIG. 21. Thus, as shown in FIGS. 21 and 22, described embodiments can be employed in audio and ultrasonic applications. In described embodiments, voltage, porosity, frequency, and other parameters of the electromechanical structures may be tuned to achieve desired response characteristics, and the values are not limited to the illustrative ranges described in regard to FIGS. 19-22.

As described herein, embodiments provide microelectromechanical and nanoelectromechanical systems (MEMS/NEMS) for sensors and actuators that can be fabricated and operated in a scalable manner over areas ranging from microns-squared to meters-squared, and on a variety of rigid, flexible, and/or transparent substrates such as plastics, semiconductors, glass, acrylics, metals, and polymer sheets. As will be described herein, embodiments provide arrays of micro- and/or nano-structured silica shells disposed between two or more opposing conductive electrodes to implement an area-scalable, mechanically compliant layer that can be actively displaced with the application of force/pressure. The mechanically compliant silica shell arrays form a dielectric layer between the two conducting plates (e.g., of a capacitor), such that a capacitance value changes based upon the displacement of the mechanically compliant dielectric layer. The mechanically compliant silica shell arrays can be manipulated by an applied stimulus to provide an electromechanical actuator, or can be manipulated by external forces to provide an electromechanical sensor.

For example, aspects of the described embodiments provide an electromechanical transducer including a mechanically compliant, elastically deformable array of dielectric shells. A first electrically conductive electrode is disposed on a first surface of the array. A second electrically conductive electrode is disposed on a second surface of the array, where the second surface opposes the first surface. The array is configured to be mechanically compliant and elastically deformable in response to one or more incident forces applied to the electromechanical transducer.

Reference herein to “one embodiment” or “an embodiment” means that a particular feature, structure, or characteristic described in connection with the embodiment can be included in at least one embodiment of the claimed subject matter. The appearances of the phrase “in one embodiment” in various places in the specification are not necessarily all referring to the same embodiment, nor are separate or alternative embodiments necessarily mutually exclusive of other embodiments. The same applies to the term “implementation.” The term “illustrative” is used herein to mean serving as an example, instance, or illustration. Any aspect or design described herein as “illustrative” is not to be construed as preferred or advantageous over other aspects or designs, but rather to present concepts in a concrete fashion.

To the extent directional terms are used in the specification and claims (e.g., upper, lower, top, bottom, parallel, perpendicular, etc.), these terms are merely intended to assist in describing the embodiments and are not intended to limit the claims. Such terms do not require exactness (e.g., exact perpendicularity or exact parallelism, etc.), but instead tolerances and ranges may apply. Similarly, unless explicitly stated otherwise, each numerical value and range should be interpreted as being approximate as if the word “about”, “substantially” or “approximately” preceded the value or range.

It should be understood that the steps of the methods set forth herein are not necessarily required to be performed in the order described, and the order of the steps of such methods should be understood to be merely illustrative. Likewise, additional steps may be included in such methods, and certain steps may be omitted or combined, in methods consistent with described embodiments.

It will be further understood that various changes in the details, materials, and arrangements of the parts that have been described and illustrated herein might be made by those skilled in the art without departing from the scope of the following claims.

1. An electromechanical transducer comprising:
a mechanically compliant, elastically deformable array of dielectric shells;
a first electrically conductive electrode disposed on a first surface of the array; and
a second electrically conductive electrode disposed on a second surface of the array, the second surface opposing the first surface;
wherein the array is configured to be mechanically compliant and elastically deformable in response to one or more incident forces applied to the electromechanical transducer.

2. The electromechanical transducer of claim 1, further comprising: a processing circuit electrically coupled to the first and second electrically conductive electrodes, the processing circuit configured to measure a variable capacitance between the first and second electrically conductive electrodes, the variable capacitance caused by mechanical compliance and elastic deformation of the array allowing a distance between the first and second electrically conductive electrodes to vary in response to a varying of the incident forces applied to the electromechanical transducer.

3. The electromechanical transducer of claim 1, further comprising: a processing circuit electrically coupled to the first and second electrically conductive electrodes, wherein the processing circuit is further configured to vary an electrostatic force between the first and second electrically conductive electrodes to cause mechanical compliance and elastic deformation of the array, thereby varying a distance between the first and second electrically conductive electrodes, thereby resulting in emission of a correspondingly varying pressure wave from the electromechanical transducer.

4. The electromechanical transducer according to claim 2, wherein the processing circuit comprises one or more of: a direct current (DC) voltage source, an alternating current (AC) voltage source, a DC current source, an AC current source, an application-specific integrated circuit (ASIC), a microprocessor, a digital signal processor (DSP), a digital-to-analog (DAC) converter, an analog-to-digital converter (ADC), an amplifier, a boost converter, and a power source.

5. The electromechanical transducer of claim 1, wherein one or both of the electrically conductive electrodes is planarized.

6. The electromechanical transducer of claim 1, wherein one of the first and second electrically conductive electrodes comprises a substrate to which the transducer is bonded.

7. The electromechanical transducer of claim 1, wherein one of the first and second electrically conductive electrodes comprises a conductive layer bonded to an insulating or semiconducting substrate.

8. The electromechanical transducer of claim 1, wherein the transducer comprises
a substrate that is coated with an electrically conducting film or has an integrated conducting region such that the substrate is operable as one of the first and second electrically conductive electrodes.

9. The electromechanical transducer of claim 1, wherein one or more physical properties of the shells are related to a corresponding responsiveness of the electromechanical transducer.

10. The electromechanical transducer of claim 9, wherein:
the one or more physical properties of the shells include one or more of: a shell diameter, a shell characteristic length, a shell shape, a shell material, and a shell wall thickness; and
the responsiveness of the electromechanical transducer includes one or more of: a stiffness of the array, a deflection stroke length of at least one of the first and second conductive electrodes, spectral sensitivity of the electromechanical transducer, and a signal-to-noise ratio of the electromechanical transducer.

11. The electromechanical transducer of claim 10, wherein the shell diameter is between approximately 2 nm and approximately 500 μm.

12. The electromechanical transducer of claim 1, wherein one or more of the shells in the array enclose a fluid within a volume of the shell.

13. The electromechanical transducer of claim 1, wherein:
the shells comprise at least one of: silica, soda-lime glass, borosilicate glass, fiberglass, or poly(methyl methacrylate);
each of the first and second electrically conductive electrodes comprises at least one of: a conductive metal, a conductive metal oxide, graphene, parylene, a conductive polymer, or doped silicon; and
a substrate of the electromechanical transducer comprises one of: glass, quartz, silicon, a plastic, a conductive metal oxide coated polymer, indium tin oxide (ITO), indium zinc oxide (IZO), aluminum zinc oxide (AZO), a conductive metal oxide coated glass, or a flexible polymer.

14. The electromechanical transducer of claim 1, wherein the one or more applied forces comprise a static or time-varying force comprising at least one of: an electrostatic force, a solid contact pressure, a haptic pressure, a fluid pressure wave, a sound wave, and an ultrasound wave.

15. The electromechanical transducer of claim 1, wherein the electromechanical transducer is optically transparent in a spectral band comprising one or more of: infra-red (IR), visible light, or ultraviolet (UV).

16. The electromechanical transducer of claim 1, wherein the array comprises a plurality of layers of dielectric shells.

17. A method of using an electromechanical transducer, the transducer comprising a mechanically compliant, elastically deformable array of dielectric shells, a first electrically conductive electrode disposed on a first surface of the array, a second electrically conductive electrode disposed on a second surface of the array, the second surface opposing the first surface, and the first and second electrically conductive electrodes electrically coupled to a processing circuit, the method comprising:
measuring, by the processing circuit, a variable capacitance between the first and second electrically conductive electrodes, the variable capacitance caused by mechanical compliance and elastic deformation of the array due to a static or time-varying incident pressure.

18. The method of claim 17, wherein the a static or time-varying incident pressure comprises at least one of: a solid contact pressure, a haptic pressure, a fluid pressure wave, a sound wave, and an ultrasound wave.

19. A method of using an electromechanical transducer, the transducer comprising a mechanically compliant, elastically deformable array of dielectric shells, a first electrically conductive electrode disposed on a first surface of the array, a second electrically conductive electrode disposed on a second surface of the array, the second surface opposing the first surface, and the first and second electrically conductive electrodes electrically coupled to a processing circuit, the method comprising:
varying, by processing circuitry via an electrical signal, an electrostatic force between the first and second electrically conductive electrodes to cause a varying elastic deformation of the array, thereby varying a distance between the first and second electrically conductive electrodes, thereby resulting in emission of a correspondingly varying pressure wave from the electromechanical transducer.

20. The method of claim 19, wherein the electrical signal varies at one or more of audio, ultrasonic and other frequencies, and wherein the emitted pressure wave varies at corresponding audio, ultrasonic or other frequencies, or wherein the emitted pressure wave comprises a haptic signal.

21. (canceled)

22. (canceled)

23. (canceled)

24. (canceled)

25. (canceled)
